(19) United States
(12) Patent Application Publication
(10) Pub. No.: US 2024/0234386 A9
(43) Pub. Date: Jul. 11, 2024

(54) LIGHT EMITTING DISPLAY DEVICE AND MANUFACTURING METHOD THEREOF

(71) Applicant: Samsung Display Co., LTD., Yongin-si (KR)

(72) Inventors: Dong Hee SHIN, Yongin-si (KR); Sun Kwun SON, Yongin-si (KR)

(21) Appl. No.: 18/480,402

(22) Filed: Oct. 3, 2023

(30) Foreign Application Priority Data
Oct. 19, 2022 (KR) 10-2022-0135123

(51) Int. Cl. H01L 25/075; H01L 25/16

(52) U.S. Cl. CPC H01L 25/0753; H01L 25/167

(57) ABSTRACT

A light emitting display device includes: a first light emitting electrode; a pixel definition layer including a light-emitting element opening exposing a part of the first light emitting electrode and including a separator; an emission layer in the light-emitting element opening; a second light emitting electrode divided by a separator; and an auxiliary insulating layer between the first light emitting electrode and the pixel definition layer and in contact with the first light emitting electrode and the pixel definition layer, wherein the separator is formed of an opening in the pixel definition layer, and an under-cut is formed under the opening in the separator.

### CROSS-REFERENCE TO RELATED APPLICATION

The present application claims priority to and the benefit of Korean Patent Application No. 10-2022-0135123 filed in the Korean Intellectual Property Office on Oct. 19, 2022, the entire content of which is incorporated herein by reference.

### BACKGROUND

### 1. Field

Aspects of some embodiments of the present disclosure relate to a light emitting display device and a manufacturing method thereof.

### 2. Description of the Related Art

A display device is a device for displaying images, and includes, for example, a liquid crystal display (LCD), an organic light emitting diode (OLED) display, and the like. The display device may be utilized in various electronic devices such as a mobile phone, a navigation device, a digital camera, an electronic book, a portable game machine, and various terminals.

Among them, the organic light emitting diode display has a self-luminance characteristic, and unlike the liquid crystal display, a separate light source may not be required, so thickness and weight may be reduced. In addition, the organic light emitting display has high quality characteristics such as low power consumption, high luminance, and relatively fast response speed.

The above information disclosed in this Background section is only for enhancement of understanding of the background and therefore the information discussed in this Background section does not necessarily constitute prior art.

### SUMMARY

Aspects of some embodiments include a light emitting display device including a separator positioned on a pixel definition layer and a manufacturing method thereof.

In addition, aspects of some embodiments include a light emitting display device and a manufacturing method thereof capable of forming a separator on a pixel definition layer without additional processes.

A light emitting display device according to some embodiments includes: a first light emitting electrode; a pixel definition layer including a light-emitting element opening exposing a part of the first light emitting electrode and including a separator; an emission layer positioned in the light-emitting element opening; a second light emitting electrode divided by a separator; and an auxiliary insulating layer positioned between the first light emitting electrode and the pixel definition layer and in contact with the first light emitting electrode and the pixel definition layer, wherein the separator is formed of an opening positioned in the pixel definition layer, and an under-cut is formed under the opening in the separator.

According to some embodiments, the under-cut may be formed by over-etching of the auxiliary insulating layer.

According to some embodiments, the auxiliary insulating layer may not be positioned on a part where the first light emitting electrode is not formed.

According to some embodiments, a separator overlapping the first light emitting electrode part overlapping the separator in a plan view and formed of the same material as the first light emitting electrode may be furher included.

According to some embodiments, the auxiliary insulating layer and the under-cut may be positioned at the upper surface of the separator overlapping first light emitting electrode part to not be in contact with the pixel definition layer, and the side of the separator overlapping first light emitting electrode part may be in contact with the pixel definition layer.

According to some embodiments, the separator overlapping first light emitting electrode part may be connected to the first light emitting electrode.

According to some embodiments, a separator overlapping second light emitting electrode part overlapping the separator, and formed of the same material as the second light emitting electrode, may be further included.

According to some embodiments, the separator overlapping second light emitting electrode part may be divided from the divided second light emitting electrode.

According to some embodiments, a second light emitting electrode connecting electrode formed of the same material as the first light emitting electrode may be further included, the pixel definition layer may further include a connection opening, and the second light emitting electrode connecting electrode and the second light emitting electrode may be in contact with and connected to each other through the connection opening.

According to some embodiments, the pixel definition layer may further include a connection opening, the first light emitting electrode may include a first/first light emitting electrode and a first/second light emitting electrode, the light-emitting element opening may include a first light-emitting element opening and a second light-emitting element opening, the emission layer may include a first emission layer positioned in the first light-emitting element opening and a second emission layer positioned in the second light-emitting element opening, the second light emitting electrode may include a second/first light emitting electrode and a second/second light emitting electrode divided by the separator, the first/first light emitting electrode, the first emission layer, and the second/first light emitting electrode may configure one light-emitting element, the first/second light emitting electrode, the second emission layer, and the second/second light emitting electrode may configure another light-emitting element, and the second/first light emitting electrode and the first/second light emitting electrode may be in contact with and connected to each other through the connection opening.

According to some embodiments, the auxiliary insulating layer may be an inorganic insulating layer including at least one of a silicon oxide (SiOx), a silicon nitride (SiNx), or a silicon oxynitride (SiOxNy), or an organic insulator including at least one material selected from the group consisting of polyimide, polyamide, acryl resin, benzocyclobutene, and phenol resin.

A manufacturing method of a light emitting display device according to some embodiments includes: sequentially stacking a first conductive material and a second insulating material on a substrate; etching the first conductive material and the second insulating material by using a first mask having a transmission region and a transflective region; stacking a third organic insulating material on the etched first conductive material and second insulating material; and etching the third organic insulating material and the etched second insulating material by using a second mask including a separator transmission region to complete a separator, the completing of the separator including etching the third organic insulating material to complete a pixel definition layer and to expose the second insulating material; and over-etching the exposed second insulating material to complete a separator having an under-cut part under the pixel definition layer.

According to some embodiments, the exposed second insulating material may be etched by a wet-etching method in the completing of the separator having the under-cut part.

According to some embodiments, the separator transmission region may not overlap the transmission region and the transflective region of the first mask.

According to some embodiments, in the completing of the separator, a separator overlapping the first light emitting electrode part overlapping the separator in a plan view and formed of the first conductive material may be formed.

According to some embodiments, in the completing of the separator, the auxiliary insulating layer formed on the second insulating material and the under-cut may be positioned on the upper surface of the separator overlapping the first light emitting electrode part not to be in contact with the pixel definition layer, and the side of the separator overlapping first light emitting electrode part may be formed to be in contact with the pixel definition layer.

According to some embodiments, the second mask may further include an opening transmission region, and the opening transmission region may overlap the transflective region of the first mask and have a narrower width than the transflective region.

According to some embodiments, the opening of the pixel definition layer completed due to the opening transmission region of the second mask and the transflective region of the first mask may not expose an auxiliary insulating layer formed of the second insulating material.

According to some embodiments, the auxiliary insulating layer may not be positioned on the portion where the first light emitting electrode formed of the first conductive material is not positioned.

According to some embodiments, the second insulating material may include an inorganic insulating material including at least one of a silicon oxide (SiOx), a silicon nitride (SiNx), a silicon oxynitride (SiOxNy), or an organic insulating material including at least one material selected from the group consisting of polyimide, polyamide, acryl resin, benzocyclobutene, and phenol resin.

According to some embodiments, the separator may be formed in the pixel definition layer by including the insulating layer between the anode and the pixel definition layer, and an additional process may not be required when forming the separator in the pixel definition layer.

### BRIEF DESCRIPTION OF THE DRAWINGS

FIG. 1 is a top plan view of a display area of a light emitting display device according to some embodiments.

FIG. 2 is a cross-sectional view of a light emitting display device according to the embodiments of FIG. 1.

FIG. 3 is a cross-sectional view of a pixel definition layer and a separator according to some embodiments.

FIG. 4 to FIG. 13 are views according to an order of manufacturing a pixel definition layer and a separator according to some embodiments.

FIG. 14 is a circuit diagram of a pixel of a light emitting display device according to some embodiments.

FIG. 15 is a circuit diagram of a pixel of a light emitting display device according to some embodiments.

FIG. 16 is a top plan view of a display area of a light emitting display device according to some embodiments.

FIG. 17 is a cross-sectional view of a light emitting display device according to the embodiments of FIG. 16.

FIG. 18 is a circuit diagram of a pixel of a light emitting display device according to some embodiments.

FIG. 19 to FIG. 21 are cross-sectional views of a light emitting display device according to some embodiments.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

In order to clarify the present invention, parts that are not connected with the description will be omitted, and the same elements or equivalents are referred to by the same reference numerals throughout the specification.

Further, because sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” or “in a plan view” refers to when an object portion is viewed from above, and the phrase “on a cross-section” means when a cross-section taken by vertically cutting an object portion is viewed from the side.

In addition, in the specification, when referring to “connected to”, this does not mean only that two or more constituent elements are directly connected to each other, but two or more constituent elements may be indirectly connected, physically connected, and electrically connected through other constituent elements, and it may be included that each of parts that are substantially integral are connected to each other although referred to by different names depending on the position or function.

Also, throughout the specification, when it is said that parts such as a wire, a layer, a film, a region, a plate, and a constituent element are “extended in a first direction or a second direction”, this does not mean only a straight line shape extending straight in the corresponding direction, but also includes a structure that is bent in a part, has a zigzag structure, or extends while including a curved line structure as a structure that extends overall along the first direction or the second direction.

In addition, electronic devices (e.g., a mobile phone, a TV, a monitor, a laptop computer, etc.) included in display devices and display panels described in the specification, or electronic devices included in display devices and display panels, etc. manufactured by manufacturing methods described in a specification, are not excluded from a scope of this specification.

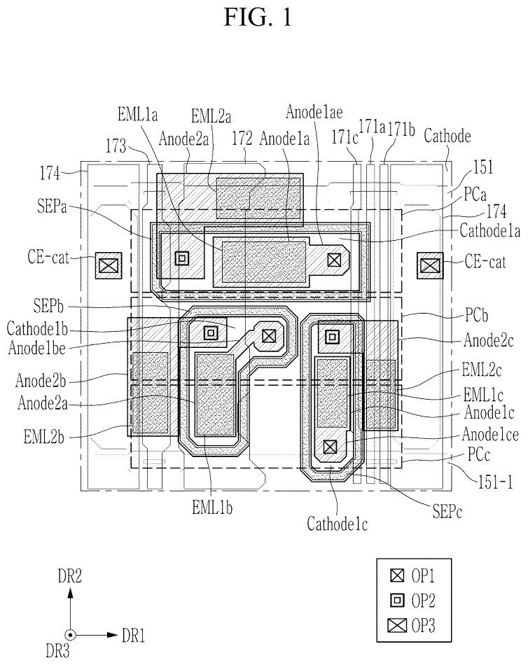

Hereinafter, a structure of a display area of a light emitting display device is described in detail with reference to accompanying drawings, and a planar structure is described through FIG. 1.

FIG. 1 is a top plan view of a display area of a light emitting display device according to some embodiments.

FIG. 1 shows a part among the display area, and one pixel includes a light-emitting element and a pixel circuit unit.

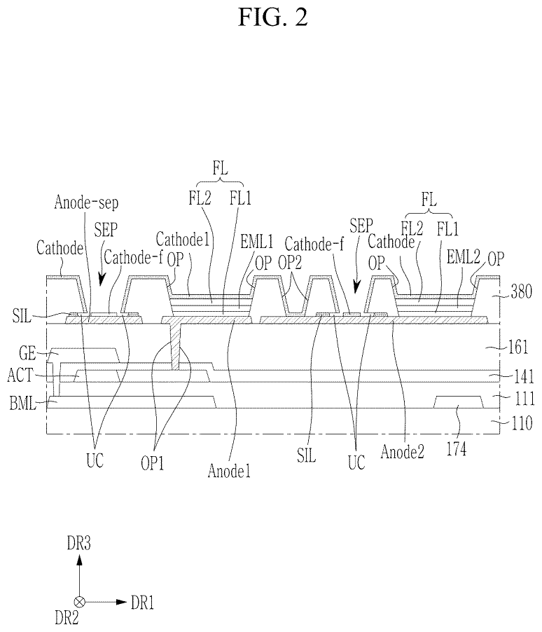

FIG. 1 mainly shows anodes Anode1a, Anode2a, Anode1b, Anode2b, Anode1c, and Anode2c, emission layers EML1a, EML2a, EML1b, EML2b, EML1c, and EML2c, cathodes Cathode, Cathode1a, Cathode1b, and Cathode1c, separators SEPa, SEPb, and SEPc, and pixel circuit units PCa, PCb, and PCc. Herein, each combination of the anodes Anode1a, Anode2a, Anode1b, Anode2b, Anode1c, and Anode2c, the emission layers EML1a, EML2a, EML1b, EML2b, EML1c, and EML2c, and the cathodes Cathode, Cathode1a, Cathode1b, and Cathode1c may configure a light-emitting element, and the combination of the light-emitting element and the pixel circuit units PCa, PCb, and PCc configure a pixel. Also, in FIG. 1, the emission layers EML1a, EML2a, EML1b, EML2b, EML1c, and EML2c, the separators SEPa, SEPb, and SEPc, and the openings OP1, OP2, and OP3 may correspond to an opening positioned in a pixel definition layer (referring to 380 of FIG. 2).

In FIG. 1, total three pixel circuit units PCa, PCb, and PCc adjacent to each other are schematically shown by a dotted line.

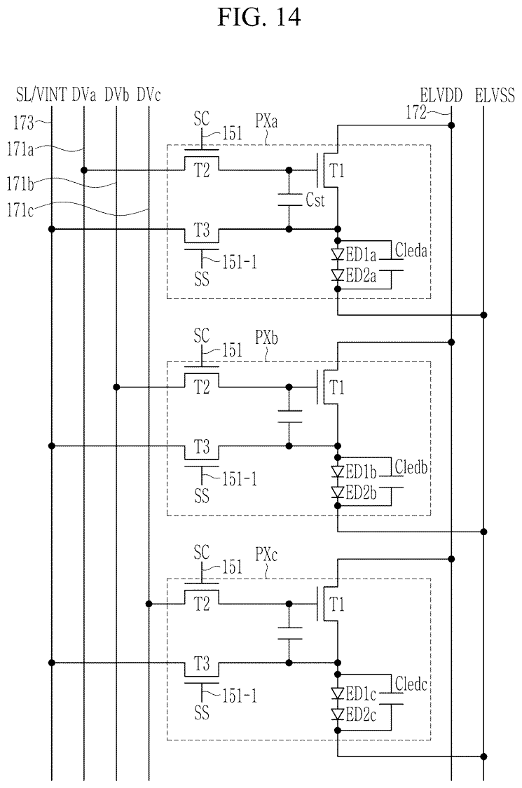

Three pixel circuit units PCa, PCb, and PCc positioned in FIG. 1 may have a structure extending long in a first direction DR1, respectively, and the three may be the pixel circuit units PCa, PCb, and PCc corresponding to the pixels displaying three primary colors of light. The structure of the pixel circuit units PCa, PCb, and PCc may vary, and according to some embodiments, they may have the same circuit structure as that of FIG. 14.

FIG. 1 additionally shows a part of wirings connected to the pixel circuit units PCa, PCb, and PCc. In FIG. 1, a first scan signal line 151 and a second scan signal line 151-1, which extend in a first direction DR1, are shown, and data lines 171a, 171b, and 171c, a driving voltage line 172, an initialization voltage line 173, and a driving low voltage line (174; referred to as a second driving voltage line), which extend in a second direction DR2, are shown.

Here, the pixel circuit units PCa, PCb, and PCc may be commonly connected to the first scan signal line 151, the second scan signal line 151-1, the driving voltage line 172, the initialization voltage line 173, and the driving low voltage line 174. Also, the first pixel circuit unit PCa is connected to the first data line 171a, the second pixel circuit unit PCb is connected to the second data line 171b, and the third pixel circuit unit PCc is connected to the third data line 171c.

Each of the pixel circuit units PCa, PCb, and PCc may correspond to one of trisection regions of the planar region partitioned by the first scan signal line 151, the second scan signal line 151-1, and the driving low voltage line 174.

In the embodiments illustrated with respect to FIG. 1, the first pixel circuit unit PCa is connected to a first/first anode Anode1a through an opening OP1, the second pixel circuit unit PCb is connected to a second/first anode Anode1b through an opening OP1, and the third pixel circuit unit PCc is connected to a third/first anode Anode1c through an opening OP1.

In the embodiments illustrated with respect to FIG. 1, the first light-emitting element may include the first/first anode Anode1a, the first/first emission layer EML1a, the first/first cathode Cathode1a, the first/second anode Anode2a, the first/second emission layer EML2a, and the cathode Cathode. The first light-emitting element may be divided into the first/first light-emitting element and the first/second light-emitting element, the first/first light-emitting element may include the first/first anode Anode1a, the first/first emission layer EML1a, and the first/first cathode Cathode1a, and the first/second light-emitting element may include the first/second anode Anode2a, the first/second emission layer EML2a, and the cathode Cathode.

In the embodiments illustrated with respect to FIG. 1, the second light-emitting element may include the second/first anode Anode1b, the second/first emission layer EML1b, the second/first cathode Cathode1b, the second/second anode Anode2b, the second/second emission layer EML2b, and the cathode Cathode. The second light-emitting element may be divided in the second/first light-emitting element and the second/second light-emitting element, the second/first light-emitting element may include the second/first anode Anode1b, the second/first emission layer EML1b, and the second/first cathode Cathode1b, and the second/second light-emitting element may include the second/second anode Anode2b, the second/second emission layer EML2b, and the cathode Cathode.

In the embodiments illustrated with respect to FIG. 1, the third light-emitting element may include the third/first anode Anode1c, the third/first emission layer EML1c, the third/first cathode Cathode1c, the third/second anode Anode2c, the third/second emission layer EML2c, and the cathode Cathode. The third light-emitting element may be divided into the third/first light-emitting element and the third/second light-emitting element, the third/first light-emitting element may include the third/first anode Anode1c, the third/first emission layer EML1c, and the third/first cathode Cathode1c, and the third/second light-emitting element may include the third/second anode Anode2c, the third/second emission layer EML2c, and the cathode Cathode.

The separators SEPa, SEPb, and SEPc may be formed in a concave structure on the pixel definition layer (referring to 380 in FIG. 2). Each of the separators SEPa, SEPb, and SEPc forms a closed curved line in a plan view, and the cathode may be separated based on the separators SEPa, SEPb, and SEPc. The separators SEPa, SEPb, and SEPc may be positioned separately at a certain distance from each other. For example, on a plane (e.g., in a plan view), the first/first cathode Cathode1a is positioned inside the first separator SEPa, the second/first cathode Cathode1b is positioned inside the second separator SEPb, the third/first cathode Cathode1c is positioned inside the third separator SEPc, and all parts positioned outside of the separator SEPa, SEPb, and SEPc correspond to the cathode Cathode. The cathode Cathode is divided into a first/first cathode Cathode1a, a second/first cathode Cathode1b, and a third/first cathode Cathode1c by the separators SEPa, SEPb, and SEPc.

The first/first anode Anode1a and the first/first emission layer EML1a are positioned inside the first separator SEPa in a plan view. The first/first cathode Cathode1a separated by the first separator SEPa constitutes the first/first light-emitting element together with the first/first anode Anode1a and the first/first emission layer EML1a. The first/first light-emitting element may be positioned within the planar first separator SEPa. Here, the first/first anode Anode1a has a connection Anode1ae protruded and extending, and the first/first anode Anode1a and the first pixel circuit unit PCa are electrically connected through the connection Anode1ae and the opening OP1, thereby receiving the current from the first pixel circuit unit PCa.

The second/first anode Anode1b and the second/first emission layer EML1b are positioned inside the second separator SEPb in a plan view. Separated by the second separator SEPb, the second/first cathode Cathode1b constitutes the second/first light-emitting element together with the second/first anode Anode1b and the second/first emission layer EML1b. The second/first light-emitting element may be positioned within the planar second separator SEPb. Here, the second/first anode Anode1b has a protruded and extended connection Anode1be, and the second/first anode Anode1b and the second pixel circuit unit PCb are electrically connected through the connection Anode1be and the opening OP1, thereby receiving the current from the second pixel circuit unit PCb.

Inside the third separator SEPc in a plan view, the third/first anode Anode1c and the third/first emission layer EML1c are positioned. Separated by the third separator SEPc, the third/first cathode Cathode1c constitutes the third/first light-emitting element together with the third/first anode Anode1c and the third/first emission layer EML1c. The third/first light-emitting element may be positioned within the third separator SEPc in a plan view. Here, the third/first anode Anode1c has a protruded and extended connection Anode1ce, and the third/first anode Anode1c and the third pixel circuit unit PCc are electrically connected through the connection Anode1ce and the opening OP1, thereby receiving the current from the third pixel circuit unit PCc.

In a plan view, outside the separators SEPa, SEPb, and SEPc, the first/second emission layer EML2a, the second/second emission layer EML2b, the third/second emission layer EML2c, and the cathode Cathode are positioned, and a part of each of the first/second anode Anode2a, the second/second anode Anode2b, and the third/second anode Anode2c is positioned.

The first/second anode Anode2a, the second/second anode Anode2b, and the third/second anode Anode2c are also partially positioned inside the planar separators SEPa, SEPb, and SEPc.

Specifically, the first/second anode Anode2a is positioned inside and outside of the first separator SEPa in a plan view, and a part overlaps with a part of the first separator SEPa. The part positioned inside the first separator SEPa among the first/second anode Anode2a is electrically connected to the first/first cathode Cathode1a through an opening (OP2; hereinafter referred to as a connection opening). The first/second anode Anode2a, the first/second emission layer EML2a, and the cathode cathode positioned outside the first separator SEPa overlap in a plan view to form the first/second light-emitting element.

The second/second anode Anode2b is positioned on the inside and outside of the second separator SEPb in a plan view, and a part overlaps a part of the second separator SEPb. The part positioned inside the second separator SEPb among the second/second anode Anode2b is electrically connected to the second/first cathode Cathode1b through the opening OP2. The second/second anode Anode2b, the second/second emission layer EML2b, and the cathode Cathode positioned outside the second separator SEPb overlap in a plan view to form the second/second light-emitting element.

The third/second anode Anode2c is positioned on the inside and outside of third separator SEPc in a plan view, and a part overlaps a part of the third separator SEPc. The part located inside the third separator SEPc among the third/second anode Anode2c is electrically connected to the third/first cathode Cathode1c through the opening OP2. The third/second anode Anode2c, the third/second emission layer EML2c, and the cathode Cathode positioned outside the third separator SEPc overlap in a plan view to form the third/second light-emitting element.

On the other hand, the cathode connecting electrode CE-cat is also positioned on the outside of the separators SEPa, SEPb, and SEPc, and electrically connects the driving low voltage line 174 and the cathode Cathode through the opening OP3 so that driving low voltage ELVSS may be transmitted to the cathode Cathode. As a result, the driving low voltage ELVSS is transmitted to each of the first light-emitting element, the second light-emitting element, and the third light-emitting element.

The light emitting display device having the planar structure of FIG. 1 as above-described is described in further detail through the cross-sectional structure of FIG. 2.

FIG. 2 is a cross-sectional view of a light emitting display device according to embodiments illustrated with respect to FIG. 1.

In FIG. 2, one light-emitting element among the first light-emitting element, the second light-emitting element, and the third light-emitting element is shown, and a path in which the current is transmitted to the second anode Anode2 and the cathode Cathode through the first anode Anode1, the first cathode Cathode1 from one transistor of the pixel circuit units PCa, PCb, and PCc is shown along with the separator SEP and the opening OP2, which are positioned in the pixel definition layer 380.

In FIG. 2, the structure of the lower part of the anodes Anode1 and Anode2 is briefly shown, and only one transistor is shown. The structure from the substrate 110 to the interlayer insulating layer 161 is described as follows.

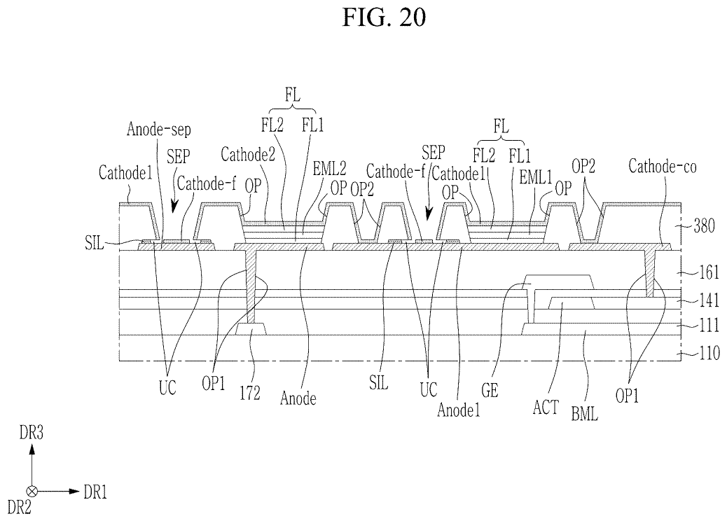

The substrate 110 may include a material that does not bend due to a rigid characteristic such as glass, or a flexible material that can be bent such as plastic or polyimide. In the case of the flexible substrate, as shown in FIG. 20, it may have a double-layered structure of polyimide, and a barrier layer formed of an inorganic insulating material thereon is formed repeatedly.

A lower shielding layer BML including a metal is positioned on the substrate 110, and the lower shielding layer BML may overlap in a plan view with one channel of transistors positioned in the pixel circuit units PCa, PCb, and PCc included in the pixel. In the embodiments illustrated with respect to FIG. 2, a driving low voltage line 174 to which a second voltage ELVSS is applied is positioned on the same layer as the lower shielding layer BML. Thus, according to some embodiments, the lower shielding layer BML may be omitted, and in this case, the driving low voltage line 174 may be positioned on another conductive layer.

The substrate 110, the lower shielding layer BML, and the driving low voltage line 174 are covered by a buffer layer 111. The buffer layer 111 serves to block penetration of impurity elements into the semiconductor layer ACT, and may be an inorganic insulating layer including a silicon oxide (SiOx), a silicon nitride (SiNx), or a silicon oxynitride (SiOxNy).

On the buffer layer 111, a semiconductor layer ACT formed of a silicon semiconductor (e.g. a polycrystalline semiconductor (P—Si)) or an oxide semiconductor is positioned. The semiconductor layer ACT is a semiconductor layer positioned in the pixel circuit units PCa, PCb, and PCc included in the pixel, and may include a channel of a transistor including a driving transistor, and a first region and a second region positioned on both sides thereof. Here, the channel of the transistor may be a portion of the semiconductor layer ACT overlapping a gate electrode GE, and the first region and the second region may be portions of the semiconductor layer ACT that do not overlap the gate electrode GE. That is, the first region and the second region positioned on both sides of the channel of the semiconductor layer ACT are not covered by the gate electrode GE, so they have the characteristics of the conductive layer by plasma treatment or doping, and may play a role of the first electrode and the second electrode of the transistor.

A first gate insulating layer 141 may be positioned on the semiconductor layer ACT. The first gate insulating layer 141 may be an inorganic insulating layer including a silicon oxide (SiOx), a silicon nitride (SiNx), a silicon oxynitride (SiOxNy), or the like.

A first gate conductive layer including a gate electrode GE of a transistor positioned in the pixel circuit units PCa, PCb, and PCc may be positioned on the first gate insulating layer 141. In the first gate conductive layer, a scan line may be formed in addition to the gate electrode GE of the transistor positioned on the pixel circuit units PCa, PCb, and PCc. Meanwhile, the first gate conductive layer may include one electrode of one capacitor positioned on the pixel circuit units PCa, PCb, and PCc. The first gate conductive layer may include a metal such as aluminum (Al), copper (Cu), molybdenum (Mo), titanium (Ti), or a metal alloy thereof, and may be configured as a single layer or multiple layers.

After forming the first gate conductive layer, the exposed region of the first semiconductor layer may be made conductive by performing a plasma treatment or a doping process. That is, the semiconductor layer ACT covered by the gate electrode GE is not conductive, and the portion of the semiconductor layer ACT not covered by the gate electrode GE may have the same characteristics as the conductive layer.

An interlayer insulating layer 161 may be positioned on the first gate conductive layer and the first gate insulating layer 141. The first interlayer insulating layer 161 may include an inorganic insulating layer including a silicon oxide (SiOx), a silicon nitride (SiNx), a silicon oxynitride (SiOxNy), and the like, and an inorganic insulating material may be thickly formed according to some embodiments. Also, according to some embodiments, the interlayer insulating layer 161 may be formed of an organic insulator, and may include at least one material selected from a group consisting of polyimide, polyamide, acryl resin, benzocyclobutene, and phenol resin.

An anode layer including the anodes Anode1 and Anode2 is positioned on the interlayer insulating layer 161, and in the embodiments illustrated with respect to FIG. 2, the anode layer includes a separator overlapping an anode part Anode-sep overlapping the separator SEP. Here, the separator overlapping anode part Anode-sep is electrically connected to the second anode Anode2 or electrically disconnected from the anodes Anode1 and Anode2. The separator overlapping anode part Anode-sep that is electrically separated from the anodes Anode1 and Anode2 may be formed in a floating structure. The anode layer may be composed of a single layer including a transparent conductive oxide film or a metal material, or a multi-layer including these. The transparent conductive oxide layer may include an indium tin oxide (ITO), a poly-ITO, an indium zinc oxide (IZO), an indium gallium zinc oxide (IGZO), and an indium tin zinc oxide (ITZO). The metal material may include silver (Ag), molybdenum (Mo), copper (Cu), gold (Au), and aluminum (Al).

An auxiliary insulating layer SIL is positioned on the anode layer including the anodes Anode1 and Anode2 and/or the separator overlapping anode part Anode-sep. The auxiliary insulating layer SIL may be positioned only on the anode layer and may not be positioned on the interlayer insulating layer 161. for the auxiliary insulating layer SIL, a part (UC; referred to as an under-cut part) where the auxiliary insulating layer SIL is removed and is not formed may be positioned above the separator overlapping anode part Anode-sep and at the portion where the separator SEP is not formed. Due to the under-cut portion UC where the auxiliary insulating layer SIL is not formed, a layer (e.g. cathode) positioned on the separator SEP may be separated based on the separator SEP. Also, among the anode layer, the area where the auxiliary insulating layer SIL is positioned may vary according to some embodiments. Here, the auxiliary insulating layer SIL is formed of an inorganic insulating layer including at least one of a silicon oxide (SiOx), a silicon nitride (SiNx), or a silicon oxynitride (SiOxNy), or may be formed of an organic insulator, and may include at least one material selected from a group consisting of polyimide, polyamide, acryl resin, benzocyclobutene, and phenol resin.

A pixel definition layer 380 having openings OP and OP2 and a separator SEP is formed on the anode layer and the auxiliary insulating layer SIL.

The opening (OP; hereinafter also referred to as a light-emitting element opening) of the pixel definition layer 380 is a portion corresponding to the light-emitting element and/or the emission layers EML1 and EML2, and exposes a portion of the anodes Anode1 and Anode2.

The opening OP2 of the pixel definition layer 380 is an opening exposing the second anode Anode2, and may be an opening for connecting the second anode Anode2 and the first cathode cathode1.

The separator SEP exposes a part of the anodes Anode1 and Anode2 or the separator overlapping the anode part Anode-sep, and the first cathode Cathode1 and the cathode Cathode are separated based on the separator SEP.

The openings OP and OP2 and the separator SEP positioned in the pixel definition layer may not expose the auxiliary insulating layer SIL, and the auxiliary insulating layer SIL may be further positioned by an under-cut portion UC that is not formed by removing the auxiliary insulating layer SIL near the separator SEP.

Within the opening OP of the pixel definition layer 380, the emission layers EML1 and EML2 are positioned, and a first functional layer FL1 may be positioned between the first anode Anode1 and the first emission layer EML1 and between the second anode Anode2 and the second emission layer EML2. Also, a second functional layer FL2 may be positioned on the first emission layer EML1 and the second emission layer EML2. Here, the first functional layer FL1 may include a hole injection layer and/or a hole transport layer, and the second functional layer FL2 may include an electron transport layer and/or an electron injection layer. Here, the combination of the functional layer FL and the emission layer EML may be referred to as an intermediate layer. According to some embodiments, the first functional layer FL1 and the second functional layer FL2 may also be formed on the pixel definition layer 380 and the opening OP, and in this case, both sides may be separated from each other based on the separator SEP. At this time, the first functional layer FL1 and the second functional layer FL2 are not positioned within the opening OP2 of the pixel definition layer 380, so that the second anode Anode2 and the first cathode Cathode1 are electrically connected, but no problem occurs.

On the second functional layer FL2, and the pixel definition layer 380 and the openings OP and OP2, a cathode layer including the first cathode Cathode1, the cathode Cathode, and the separator overlapping cathode part Cathode-f is formed. Referring to FIG. 2, the separator overlapping cathode part Cathode-f may be positioned on the separator overlapping anode part Anode-sep exposed by the separator SEP. The separator overlapping cathode part Cathode-f can be formed on a part of the separator SEP, but it is separated from the first cathode cathode1 and the cathode Cathode on both sides based on the separator SEP. Here, the separator overlapping cathode part Cathode-f may be floating and no voltage may be applied.

In the embodiments illustrated with respect to FIG. 2, that the first cathode Cathode1 and the cathode Cathode are disconnected from the separator overlapping cathode part Cathode-f based on the separator SEP is due to the under-cut portion UC where the auxiliary insulating layer SIL positioned under the pixel definition layer 380 is over-etched and then removed. That is, the openings OP and OP2 and the separator SEP positioned on the pixel definition layer 380 have the tapered sides so that the layer positioned thereon may be continuously stacked, but the overlying layer may be disconnected and separated due to the under-cut portion UC positioned below the separator SEP.

Meanwhile, according to some embodiments, the functional layer FL may be positioned between the separator overlapping anode part Anode-sep and the separator overlapping cathode part Cathode-f. At this time, the functional layer FL may also have a separator overlapping functional layer, such as the separator overlapping cathode part Cathode-f, and may have a structure that is separated from the functional layers on both sides.

Referring to FIG. 2, among the semiconductor layer ACT of the transistor, the part serving as the second electrode and the first anode Anode1 are electrically connected through the opening OP1 positioned on the interlayer insulating layer 161, and the current is transmitted to the first anode Anode1.

The current transmitted to the first anode Anode1 is transmitted to the first cathode Cathode1 through the first functional layer FL1, the first emission layer EML1, and the second functional layer FL2. At this time, the first emission layer EML1 emits light due to the current flowing through the first emission layer EML1, and the first light-emitting element exhibits luminance.

Meanwhile, the first cathode Cathode1 is electrically connected to the second anode Anode2 through the opening OP2 positioned on the pixel definition layer 380. As a result, the current is also transmitted to the second anode Anode2, and the current transmitted to the second anode Anode2 passes through the first functional layer FL1, the second emission layer EML2, and the second functional layer FL2 and is transmitted to the cathode Cathode. At this time, the second emission layer EML2 emits light due to the current flowing through the second emission layer EML2, and the second light-emitting element shows luminance.

According to some embodiments, some pixel of three pixels of FIG. 1 may have a structure in which the first anode Anode1 and the second anode Anode2 are integrally formed, the first emission layer EML1 and the second emission layer EML2 are integrally formed, and the first cathode Cathode1 and the cathode Cathode are integrally formed, thereby including only one light-emitting element. Including two or more light-emitting elements rather than one pixel including one light-emitting element has the merit of improving power consumption.

On the other hand, according to some embodiments, a spacer may be further formed on the pixel definition layer 380, and the spacer may have a tapered side wall to prevent the cathode from being cut.

In FIG. 2, a structure on the cathode is not shown, but the encapsulation layer may be positioned according to some embodiments. The encapsulation layer may include at least one inorganic layer and at least one organic layer, and may have a three-layer structure including a first inorganic encapsulation layer, an organic encapsulation layer, and a second inorganic encapsulation layer. The encapsulation layer may be for protecting the emission layer EML from moisture or oxygen that may inflow from the outside. According to some embodiments, the encapsulation layer may include a structure in which an inorganic layer and an organic layer are further sequentially stacked.

According to some embodiments, a sensing insulating layer and a plurality of sensing electrodes may be positioned on the encapsulation layer for touch sensing.

According to some embodiments, a film including a polarizer may be attached on the encapsulation layer to reduce reflection of external light, or a color filter or a color conversion layer may be further formed to improve color quality. A light blocking layer may be positioned between the color filter or the color conversion layer. Also, according to some embodiments, a layer in which a material (hereinafter referred to as a reflection control material) capable of absorbing some wavelengths of external light is formed may be further included. In addition, according to some embodiments, the entire surface of the light emitting display device may be flattened by being covered with an additional organic film (also referred to as a planarization film).

FIG. 2 is a cross-sectional structure according to some embodiments, so numerous variations of the structure may be possible.

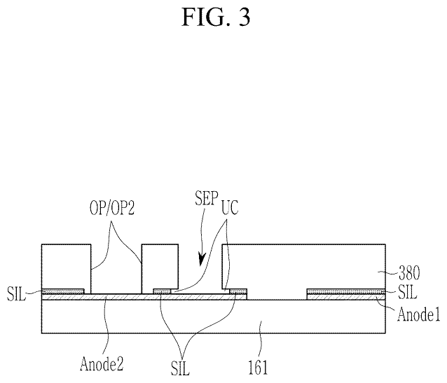

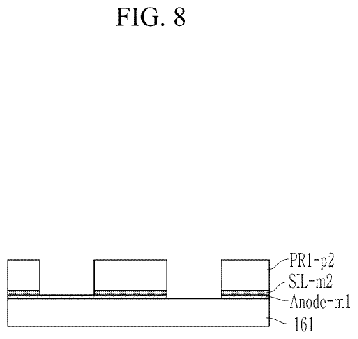

Hereinafter, the structure of the anode layer, the auxiliary insulating layer SIL, and the pixel definition layer 380, and the manufacturing method thereof, will be described through FIG. 3 to FIG. 13.

First, the cross-sectional structure of the anode layer, the auxiliary insulating layer SIL, and the pixel definition layer 380 is described through FIG. 3.

FIG. 3 is a cross-sectional view showing a pixel definition layer and a separator according to some embodiments.

FIG. 3 shows the cross-sectional structure formed to the pixel definition layer 380 among the cross-section of the light emitting display device of FIG. 2, the portions corresponding to two openings OP and OP2 are shown as one combination in FIG. 2, and the part where the separator SEP is formed is shown separately.

According to the opening OP/OP2 shown as one in FIG. 3, a portion of the second anode Anode2 of the anode layer may be exposed. Depending on the position, the first anode Anode1 of the anode layer may be exposed. The opening OP/OP2 exposes only the anode layer, and the auxiliary insulating layer SIL may not be exposed. That is, the auxiliary insulating layer SIL may etched in an area larger than the opening OP/OP2 and covered with the pixel definition layer 380, so it may not be exposed through the opening OP/OP2.

In the opening OP/OP2 shown as one in FIG. 3, if the functional layer, the emission layer, and the cathode layer are formed, it corresponds to the opening OP in which the light-emitting element is formed, and if only the cathode layer is formed without the functional layer and the emission layer, the opening OP2 for connecting the anode layer and the cathode layer is formed.

On the other hand, FIG. 3 shows the structure of the separator SEP, and one part of the second anode Anode2 of the exposed anode layer may be confirmed. The auxiliary insulating layer SIL is positioned between the pixel definition layer 380 and the second anode Anode2 surrounding the separator SEP, and the under-cut portion UC where the auxiliary insulating layer SIL is over-etched and removed is positioned. As a result, the upper surface of the second anode Anode2 overlapping the result separator SEP does not come into contact with the pixel definition layer 380, and the side surface of the second anode Anode2 may come into contact with the pixel definition layer 380. The auxiliary insulating layer SIL or the under-cut portion UC may be positioned on the upper surface of the second anode Anode 2 so that it may not come into contact with the pixel definition layer 380. The auxiliary insulating layer SIL may have a portion exposed to the outside without being covered by the pixel definition layer 380 by the separator SEP and the under-cut portion UC.

Also, FIG. 3 shows the first anode Anode1 of the anode layer covered by the pixel definition layer 380 and the auxiliary insulating layer SIL, and the position of the auxiliary insulating layer SIL on the first anode Anode1 may be vary.

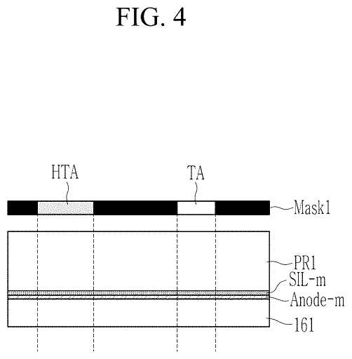

Hereinafter, the method for manufacturing the anode layer, the auxiliary insulating layer SIL, and the pixel definition layer 380 according to the embodiments like FIG. 3 is sequentially described with reference to FIG. 4 to FIG. 13.

FIG. 4 to FIG. 13 are views according to an order of manufacturing a pixel definition layer and a separator according to some embodiments.

First, referring to FIG. 4, on an interlayer insulating layer 161 positioned on a substrate, an anode layer material (Anode-m; hereinafter referred to as a first conductive material) and an auxiliary insulating layer material (SIL-m; hereinafter referred to as a second insulating material) are sequentially stacked, and a first photoresist PR1 is stacked. After that, the first photoresist PR1 is exposed using a first mask Mask1 having a transmission region TA and a transflective region (HTA). Here, the auxiliary insulating layer material SIL-m may include an inorganic insulating material including at least one among a silicon oxide (SiOx), a silicon nitride (SiNx), a silicon oxynitride (SiOxNy), or an organic insulating material including at least one material selected from the group consisting of polyimide, polyamide, acryl resin, benzocyclobutene, and phenolic resin.

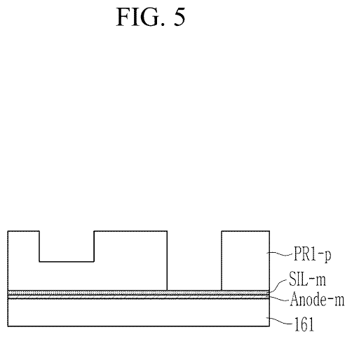

Referring to FIG. 5, a first photoresist PR1 exposed by the first mask Mask1 after developing is shown. That is, in the portion exposed by the transmission region TA of the first mask Mask1, the first photoresist PR1 is completely removed to expose the auxiliary insulating layer material SIL-m. In addition, a portion of the first photoresist PR1 exposed by the transflective region HTA of the first mask Mask1 is removed, and the unexposed first photoresist PR1 remains. As a result, the developed first photoresist pattern PR1-p such as in FIG. 5 is formed. However, depending on the nature of the first photoresist PR1, the region unexposed through the development may be removed.

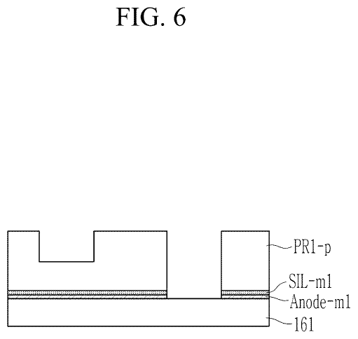

Next, when performing an etching process, the auxiliary insulating layer material SIL-m and the anode layer material Anode-m of the portion that is not covered by the first photoresist pattern PR1-p developed like in FIG. 6 are etched and removed, thereby a first auxiliary insulating layer pattern SIL-m1 and a first anode layer pattern Anode-m1 are formed.

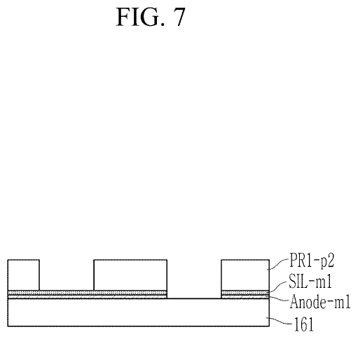

After that, as shown in FIG. 7, when an etch back process is performed, the developed first photoresist pattern PR1-p is entirely removed and the height thereof is lowered, and an etched-back first photoresist pattern PR1-p2 in which the first photoresist PR1 of the exposed part by the transflective region HTA is all removed is completed. As a result, the upper surface of the first anode layer pattern Anode-m1 of the portion exposed by the transflective region HTA is exposed.

Next, the exposed first auxiliary insulating layer pattern SIL-m1 is etched by using the etched-back first photoresist pattern PR1-p2 as a mask to complete a second auxiliary insulating layer pattern SIL-m2. At this time, because the first anode layer pattern Anode-m1 positioned at the bottom is not etched, the same pattern as that in FIG. 7 is maintained.

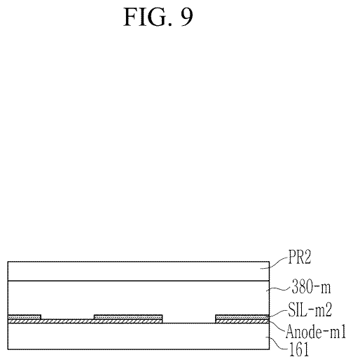

Next, as shown in FIG. 9, a pixel definition layer material (380-m; hereinafter referred to as a third organic insulating material) and a second photoresist PR2 are stacked over the entire region.

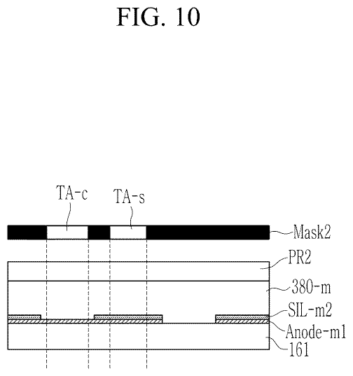

Next, as shown in FIG. 10, the second photoresist PR2 is exposed by using a second mask Mask2 having two transmission regions TA-s and TA-c. Here, the two transmission regions TA-s and TA-c are divided into a separator transmission region TA-s and an opening transmission region TA-c. The separator transmission region TA-s does not overlap the transmission region TA of the first mask Mask1 and the transflective region HTA, and corresponds to a light blocking region. In addition, the opening transmission region TA-c corresponds to and overlaps the opening OP/OP2 of the pixel definition layer 380, and corresponds to the transflective region HTA of the first mask Mask1. In this case, the opening transmission region TA-c of the second mask Mask2 may have a narrower width than the transflective region HTA of the first mask Mask1.

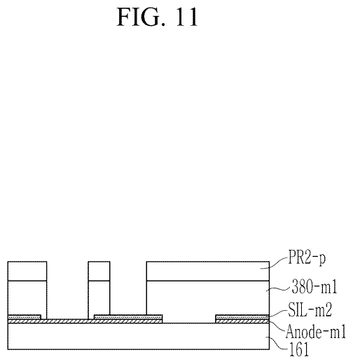

Referring to FIG. 11, after completing a developed second photoresist PR2-p by developing the exposed second photoresist PR2, the exposed pixel definition layer material 380-m is etched by using the developed second photoresist PR2-p as a mask to form a first pixel definition layer pattern 380-m1. Here, the first pixel definition layer pattern 380-m1 may be the same pattern as the completed pixel definition layer 380. Also, in FIG. 11, by etching the pixel definition layer material 380-m, the second auxiliary insulating layer pattern SIL-m2 of the part corresponding to the separator transmission region TA-s is exposed while completing the pixel definition layer 380. On the other hand, because the opening transmission region TA-c of the second mask Mask2 has the narrower width than the transflective region HTA of the first mask Mask1, the second auxiliary insulating layer pattern SIL-m2 adjacent to the opening transmission region TA-c is covered by the first pixel definition layer pattern 380-m1, thereby having the non-exposed structure. Therefore, the openings OP and OP2 formed in the pixel definition layer 380 in the completed structure do not expose the auxiliary insulating layer SIL.

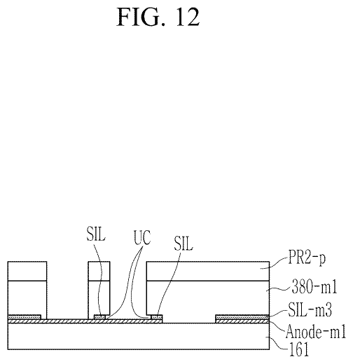

After that, as shown in FIG. 12, the exposed second auxiliary insulating layer pattern SIL-m2 is etched by using the developed second photoresist PR2-p as a mask to complete a third auxiliary insulating layer pattern SIL-m3. At this time, as the exposed second auxiliary insulating layer pattern SIL-m2 is over-etched, an under-cut portion UC is formed under the first pixel definition layer pattern 380-m1. In order to form the under-cut portion UC, the third auxiliary insulating layer pattern SIL-m3 may be completed through wet etching or dry etching of the second auxiliary insulating layer pattern SIL-m2. At this time, an etchant used during the wet etching does not etch the pixel definition layer material and the anode layer material, and an etchant capable of etching only the auxiliary insulating layer material may be selected and used.

In the case of the wet etch, the etchant also etches the side surface of the second auxiliary insulating layer pattern SIL-m2 that is not exposed by the first pixel definition layer pattern 380-m1 along the upper surface of the first anode layer pattern Anode-m1, thereby forming the under-cut portion UC. In addition, in the case of the dry etching, the size of the under-cut portion UC may be smaller than that of the wet etching, but the side surface of the second auxiliary insulating layer pattern SIL-m2 is also partially etched, resulting in the under-cut portion UC. During the dry etching, the under-cut portion UC may be formed by adjusting the etching direction.

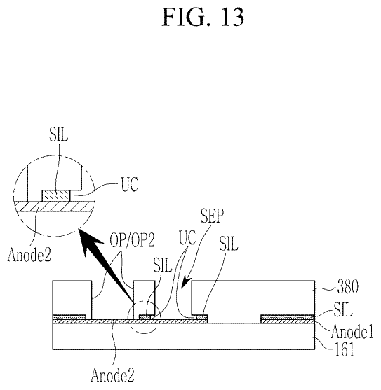

After going through the etching process of FIG. 12, the second photoresist PR2-p is removed by a stripper, thereby completing the structure of FIG. 13. The structure of FIG. 13 may have the same structure as the structure shown in FIG. 3.

The method for manufacturing the anode layer, the auxiliary insulating layer SIL, and the pixel definition layer 380 according to the above description may be described briefly as follows.

The method may include: sequentially stacking the first conductive material and the second insulating material on the substrate; etching the first conductive material and the second insulating material by using the first mask having the transmission region and the transflective region; stacking the third organic insulating material on the etched first conductive material and second insulating material; and etching the third organic insulating material and the etched second insulating material by using the second mask including the separator transmission region to complete the separator, wherein the completing of the separator includes etching the third organic insulating material to complete the pixel definition layer and to expose the second insulating material, and over-etching the exposed second insulating material to complete the separator having the under-cut part under the pixel definition layer.

After that, the functional layer, the emission layer, and the cathode layer are stacked, thereby completing the structure like FIG. that of FIG. 2. Here, the functional layer, the emission layer, and the cathode layer may be sequentially formed on the opening OP where the light-emitting element is formed, and only the cathode layer is formed on the opening OP2 connecting the anode layer and the cathode layer so as to be in contact with the anode layer. On the other hand, when the cathode layer is stacked on the separator SEP, the cathode layer is separated due to the under-cut portion UC, and the separator overlapping cathode part Cathode-f, the first cathode Cathode1, and the cathode Cathode are formed to be separated.

According to the structure of the above separator SEP, the stacked layers may be separated without a separate etching process. According to some embodiments, the functional layer may also be formed as a whole and positioned below the cathode layer, and may have a structure separated by the separator SEP. At this time, the functional layer is not positioned within the opening OP2 of the pixel definition layer 380, so that problems may not occur when the second anode Anode2 and the first cathode Cathode1 are electrically connected.

The pixel of the light emitting display device according to the embodiments illustrated with respect to FIG. 1 to FIG. 13 may have the same circuit structure as that of FIG. 14.

FIG. 14 is a circuit diagram of a pixel of a light emitting display device according to some embodiments.

In FIG. 14, as shown in FIG. 2, the circuit diagram of three pixels PXa, PXb, and PXc is shown.

A plurality of pixels may include a first pixel PXa, a second pixel PXb, and a third pixel PXc. Each of the first pixel PXa, the second pixel PXb, and the third pixel PXc include a plurality of transistors T1, T2, and T3, a storage capacitor Cst, and a pair of light-emitting elements EDa1, EDa2, EDb1, EDb2, EDc1, and EDc2. Here, one pixel of PXa, PXb, and PXc may be divided into a pair of light-emitting elements EDa1, EDa2, EDb1, EDb2, EDc1, and EDc2 and a pixel circuit unit PCa, PCb, and PCc, and the pixel circuit unit PCa, PCb, and PCc may correspond to the part shown by a dotted line in FIG. 1. Referring to FIG. 14, the pixel circuit units PCa, PCb, and PCc correspond to the part excluding a pair of light-emitting elements EDa1, EDa2, EDb1, EDb2, EDc1, and EDc2 in each pixel PXa, PXb, and PXc, and may include a plurality of transistors T1, T2, and T3 and the storage capacitor Cst.

In addition, according to some embodiments, capacitors Cleda, Cledb, and Cledc (hereinafter referred to as a light-emitting part capacitor) connected to both ends of a pair of light-emitting elements EDa1, EDa2, EDb1, EDb2, EDc1, and EDc2 may be further included, and the light-emitting capacitors Cleda, Cledb, and Cledc may not be included in the pixel circuit unit, but may be included in the light-emitting element EDa, EDb, and EDc.

A plurality of transistors T1, T2, and T3 are formed of one driving transistor T1 (referred to as a first transistor) and two switching transistors T2 and T3, and two switching transistors are divided into an input transistor T2 (referred to as a second transistor) and an initialization transistor T3 (referred to as a third transistor). Each transistor T1, T2, and T3 includes a gate electrode, a first electrode, and a second electrode, and also includes a semiconductor layer including a channel, thereby a current flows or is blocked to the channel of the semiconductor layer depending on the voltage of the gate electrode. Here, one of the first electrode and the second electrode may be a source electrode and the other may be a drain electrode according to the voltage applied to each transistor T1, T2, and T3.

The gate electrode of the driving transistor T1 is connected to one end of the storage capacitor Cst, and is also connected to the second electrode (an output electrode) of the input transistor T2. Also, the first electrode of the driving transistor T1 is connected to a driving voltage line 172 transmitting a driving voltage ELVDD, and the second electrode of the driving transistor T1 is connected to a first anode of the first light-emitting element EDa1, EDb1, and EDc1, the other terminal of the storage capacitor Cst, the first electrode of the initialization transistor T3, and one terminal of the light-emitting part capacitors Cleda, Cledb, and Cledc. The driving transistor T1 may receive a data voltage DVa, DVb, and DVc to the gate electrode according to the switching operation of the input transistor T2, and supply the driving current to a pair of light-emitting elements EDa1, EDa2, EDb1, EDb2, EDc1, and EDc2. At this time, the storage capacitor Cst stores and maintains the voltage of the gate electrode of the driving transistor T1.

The gate electrode of the input transistor T2 is connected to a first scan signal line 151 delivering a first scan signal SC. The first electrode of the input transistor T2 is connected to data lines 171a, 171b, and 171c transmitting data voltages DVa, DVb, and DVc, and the second electrode of the input transistor T2 is connected to one terminal of the the storage capacitor Cst and the gate electrode of the driving transistor T1. A plurality of data lines 171a, 171b, and 171c transmit the different data voltages DVa, DVb, and DVc, respectively, and the input transistor T2 of each pixel PXa, PXb, and PXc is connected to the different data lines 171a, 171b, and 171c. The gate electrode of the input transistor T2 of each pixel PXa, PXb, a PXc is connected to the same first scan signal line 151 and may receive the first scan signal SC at the same timing. Even if the input transistor T2 of each pixel PXa, PXb, a PXc is turned on simultaneously by the first scan signal SC of the same timing, the different data voltages DVa, DVb, and DVc through the different data lines 171a, 171b, and 171c are transmitted to one terminal of the storage capacitor Cst and the gate electrode of the driving transistor T1 of each pixel PXa, PXb, a PXc.

The embodiments illustrated with respect to FIG. 14 are embodiments in which the gate electrode of the initialization transistor T3 receives the different scan signal from the gate electrode of the input transistor T2.

The gate electrode of the initialization transistor T3 is connected to the second scan signal line 151-1 that transmits the second scan signal SS. The first electrode of the initialization transistor T3 is connected to the other terminal of the storage capacitor Cst, the second electrode of the driving transistor T1, the first anode of the first light-emitting element EDa1, EDb1, and EDc1, and one terminal of the light-emitting part capacitor Cleda, Cledb, and Cledc, and the second electrode of the initialization transistor T3 is connected to the initialization voltage line 173 transmitting the initialization voltage VINT. As the initialization transistor T3 is turned on depending on the second scan signal SS, the initialization voltage VINT is transmitted to the first anode of the first light-emitting elements EDa1, EDb1, and EDc1, one terminal of the light-emitting part capacitors Cleda, Cledb, and Cledc, and the other terminal of the the storage capacitor Cst to initialized the voltage of the first anode of the first light-emitting elements EDa1, EDb1, and EDc1.

The initialization voltage line 173 may serve as sensing wiring SL by performing an operation of sensing the voltage of the first anode of the first light-emitting elements EDa1, EDb1, and EDc1 before applying the initialization voltage VINT. Through the sensing operation, it may be checked whether the voltage of the first anode is maintained at the target voltage. The sensing operation and the initialization operation that transmits the initialization voltage VINT may be separated in time, and the initialization operation may be performed after the sensing operation is performed.

In the embodiments illustrated with respect to FIG. 14, because the turn-on period of the initialization transistor T3 and the input transistor T2 may be distinguished, the write operation performed by the input transistor T2 and the initialization operation (and/or a detection operation) performed by the input transistor T3 may be performed at different timings.

One terminal of the storage capacitor Cst is connected to the gate electrode of the driving transistor T1 and the second electrode of the input transistor T2, the other terminal thereof is connected to the first electrode of the initialization transistor T3, the second electrode of the driving transistor T1, the first anode of the first light-emitting element EDa1, EDb1, and EDc1, and one terminal of the light-emitting part capacitors Cleda, Cledb, and Cledc.

A pair of light-emitting elements EDa1, EDa2, EDb1, EDb2, EDc1, and EDc2 have a structure in which the first cathode of the first light-emitting element EDa1, EDb1, and EDc1 and the second anode of the second light-emitting elements EDa2, EDb2, and EDc2 are electrically connected, and the output current of the driving transistor T1 is transmitted to the first anode of the first light-emitting elements EDa1, EDb1, and EDc1. The cathode of the second light-emitting elements EDa2, EDb2, and EDc2 revives the driving low voltage ELVSS through the driving low voltage line 174, and a pair of light-emitting elements EDa1, EDa2, EDb1, EDb2, EDc1, and EDc2 emit light according to the output current of driving transistor T1 to display a gray.

Also, the light-emitting part capacitors Cleda, Cledb, and Cledc are formed on both terminals of a pair of light-emitting elements EDa1, EDa2, EDb1, EDb2, EDc1, and EDc2 so that the voltage between both terminals of a pair of light-emitting elements EDa1, EDa2, EDb1, EDb2, EDc1, and EDc2 may be constantly maintained, thereby a pair of light-emitting elements EDa1, EDa2, EDb1, EDb2, EDc1, and EDc2 may display a constant luminance.

Hereinafter, the operation of the pixel having the circuit like FIG. 14 is simply described.

FIG. 14 illustrates aspects of embodiments in which each transistor T1, T2, and T3 is an N-type transistor, and has a characteristic of being turned on when a high level voltage is applied to the gate electrode. However, according to some embodiments, each transistor T1, T2, and T3 may be a P-type transistor.

While the light emitting period is finished, one frame begins. After that, the second scan signal SS of a high level is supplied and the initialization transistor T3 is turned on. When the initialization transistor T3 is turned on, the initialization operation and/or the sensing operation may be performed.

The embodiments where both the initialization operation and the detection operation are performed are further described below.

The detection operation may be performed before the initialization operation is performed. That is, as the initialization transistor T3 is turned on, the initialization voltage line 173 plays the role of the detection wiring SL to detect the voltage of the first anode of the first light-emitting elements EDa1, EDb1, and EDc1. Through the detection operation, it may be checked whether the voltage of the anode is maintained as the target voltage.

Next, the initialization operation may be performed by changing the voltage of the other terminal of the storage capacitor Cst, the second electrode of the driving transistor T1, and the first anode of the first light-emitting elements EDa1, EDb1, and EDc1 into the initialization voltage VINT transmitted from the initialization voltage line 173.

In this way, the detection operation and the initialization operation that transmits the initialization voltage VINT are separated in time, so that the pixel may perform the various operations while using a minimum number of transistors and reducing the area occupied by the pixel. As a result, the resolution of the display panel may be improved.

Along with the initialization operation or at separate timing, the first scan signal SC is also changed to a high level and applied, the input transistor T2 is turned on, and the writing operation is performed. That is, the data voltages DVa, DVb, and DVc from data lines 171a, 171b, and 171c are input to the gate electrode of the driving transistor T1 and one terminal of the storage capacitor Cst through the turned-on input transistor T2 and stored.

By the initialization operation and the writing operation, the data voltages DVa, DVb, and DVc and the initialization voltage VINT are applied to both terminals of the storage capacitor Cst, respectively. In the state that the initialization transistor T3 is turned on, even if the output current is generated in the driving transistor T1, it may be output to the outside through the initialization transistor T3 and the initialization voltage line 173 and may not be input to the first anode of the first light-emitting elements EDa1, EDb1, and EDc1. Also, according to some embodiments, during the writing period at which the first scan signal SC of a high level is supplied, by applying the driving voltage ELVDD as a low level voltage or the driving low voltage ELVSS as a high level voltage, the current may not flow to a pair of light-emitting elements EDa1, EDa2, EDb1, EDb2, EDc1, and EDc2.

Next, if the first scan signal SC is changed into low level, the driving transistor T1 generates and outputs an output current according to the driving voltage ELVDD of a high level applied to the driving transistor T1 and the gate voltage of the driving transistor T1 stored in the storage capacitor Cst. The output current of the driving transistor T1 is input to a pair of light-emitting elements EDa1, EDa2, EDb1, EDb2, EDc1, and EDc2 so that a light emitting period in which a pair of light-emitting elements EDa1, EDa2, EDb1, EDb2, EDc1, and EDc2 emit light proceeds.

In the above, the pixels where each pixel includes a pair of light-emitting elements as shown in FIG. 1 and FIG. 2 have been described through FIG. 14. That is, a pair of light-emitting elements as the structure in which the first cathode of the first light-emitting element and the second anode of the second light-emitting element are electrically connected have the structure in which the output current of the driving transistor T1 is transmitted to the first anode of the first light-emitting element.

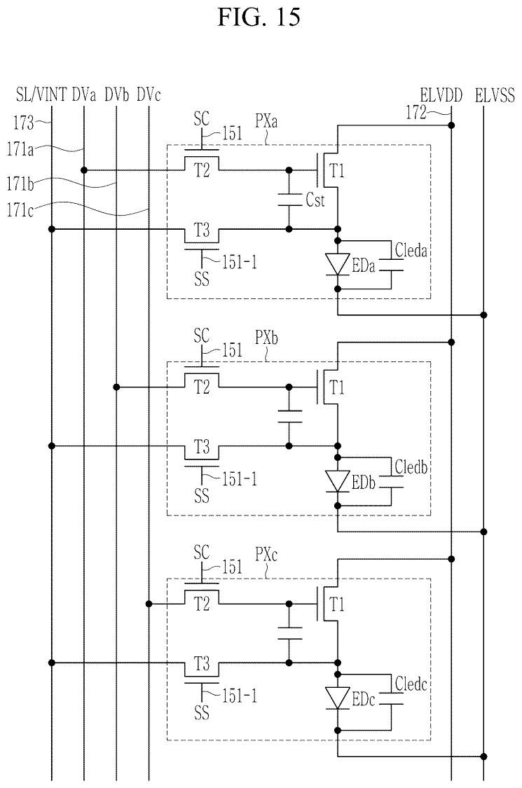

However, according to some embodiments, one pixel may include only one light-emitting element, and the circuit structure according to some embodiments is further described with respect to FIG. 15.

FIG. 15 is a circuit diagram of a pixel of a light emitting display device according to some embodiments.

In the embodiments illustrated with respect to FIG. 15, unlike the embodiments of FIG. 14, one pixel PXa, PXb, and PXc includes one of light-emitting elements EDa, EDb, and EDc, respectively. The other circuit structure of each pixel circuit units PCa, PCb, and PCc is the same. The circuit structure and the operation of each pixel circuit unit PCa, PCb, and PCc of the embodiments of FIG. 15 may be the same as that of FIG. 14 so that some repetitive description thereof may be omitted.

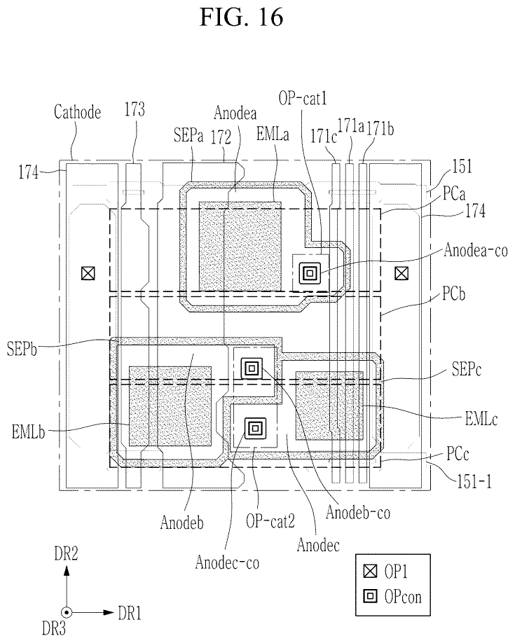

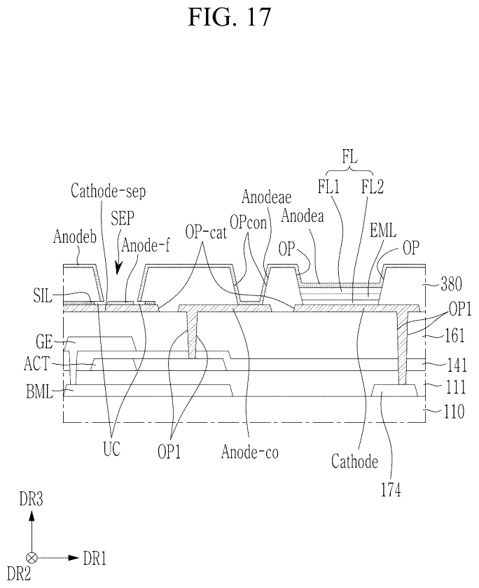

The embodiments having the pixel circuit structure like FIG. 15 may have the planar structure and the cross-sectional structure as shown in FIG. 16 and FIG. 17.

In the embodiments illustrated with respect to FIG. 16 and FIG. 17, anodes Anodea, Anodeb, and Anodec are separated by using a separators SEPa, SEPb, and SEPc, unlike FIG. 1, and a cathode Cathode is positioned under a pixel definition layer 380. The cathode Cathode has openings OP-cat1 and OP-cat2, and a current is transmitted to the anodes Anodea, Anodeb, and Anodec positioned on the pixel definition layer 380 through the openings OP-cat1 and OP-cat2.

First, the planar structure is described through FIG. 16.

FIG. 16 is a top plan view of a display area of a light emitting display device according to some embodiments.

FIG. 16 shows a part of the display area, and one pixel includes the light-emitting element and the pixel circuit unit.

FIG. 16 focuses the anodes Anodea, Anodeb and Anodec, the emission layers EMLa, EMLb, and EMLc, the cathode Cathode, the separators SEPa, SEPb, and SEPc, and the pixel circuit units PCa, PCb, and PCc. Here, each combination of the anodes Anodea, Anodeb, and Anodec, the emission layers EMLa, EMLb, and EMLc, and the cathode Cathode may configure the light-emitting element, and the light-emitting element and the pixel circuit units PCa, PCb, and PCc together constitute a pixel. Also, in FIG. 16, the emission layers EMLa, EMLb, and EMLc, the separators SEPa, SEPb and SEPc and the openings OP-cat1 and OP-cat2 may correspond to openings positioned in a pixel definition layer (referring to 380 of FIG. 17).

In the embodiments illustrated with respect to FIG. 16, as shown in FIG. 1, the pixel circuit units PCa, PCb, and PCc are schematically shown with a dotted line, and a first scan signal line 151, a second scan signal line 151-1, data lines 171a, 171b, and 171c, a driving voltage line 172, an initialization voltage line 173, and a driving low voltage line 174 positioned therearound are shown. Their structure is the same as that in FIG. 1, so some repetitive description thereof may be omitted.

In the embodiments illustrated with respect to FIG. 16, the first pixel circuit unit PCa is connected to the first anode Anodea through an opening OPcon (hereinafter; referred to as a connection opening), and a first anode connecting part Anodea-co, the second pixel circuit unit PCb is connected to the second anode Anode through an opening OPcon and a second anode connecting part Anodeb-co, and the third pixel circuit unit PCc is connected to the third anode Anodec through an opening OPcon and a third anode connecting part Anodec-co. Here, the first anode connecting part Anodea-co, the second anode connecting part Anodeb-co, and the third anode connecting part Anodec-co may be positioned within the openings OP-cat1 and OP-cat2 positioned in the cathode Cathode.

In the embodiments illustrated with respect to FIG. 16, the first light-emitting element may consist of the first anode Anodea, the first emission layer EMLa, and the cathode Cathode, the second light-emitting element may consist of the second anode Anodeb, the second emission layer EMLb, and the cathode Cathode, and the third light-emitting element may consist of the third anode Anodec, the third emission layer EMLc, and the cathode Cathode.

The cathode Cathode may be formed over the entire display area except for the openings OP-cat1 and OP-cat2. On the other hand, the cathode Cathode is connected to the driving low voltage line 174 positioned below through the opening OP1 to receive the driving low voltage ELVSS. Within the openings OP-cat1 and OP-cat2 positioned in the cathode Cathode, the first anode connecting part Anodea-co, the second anode connecting part Anodeb-co, and the third anode connecting part Anodec-co may be positioned.

The separators SEPa, SEPb, and SEPc may be formed with a concave structure in the pixel definition layer (referring to 380 of FIG. 17). The separators SEPa, SEPb, and SEPc form a closed curved line in a plan view, respectively, and the anodes may be separated based on the separators SEPa, SEPb, and SEPc. The separators SEPa, SEPb, and SEPc may be separated and positioned at a certain distance from each other, but referring to FIG. 16, they may be formed into a structure that shares at least some of the separators SEPa, SEPb, and SEPc. In the embodiments illustrated with respect to FIG. 16, the second separator SEPb and the third separator SEPc have a structure in which a part thereof is shared.

In a plan view, the first anode Anodea is positioned inside the first separator SEPa, the second anode Anodeb is positioned inside the second separator SEPb, and the third anode Anodec is positioned inside the third separator SEPc. On the outside of the separators SEPa, SEPb, and SEPc, an auxiliary electrode made of the same material as the anodes Anodea, Anodeb, and Anodec may be positioned. The auxiliary electrode may be floating or a constant voltage such as the driving low voltage ELVSS may be applied.

In a plan view, the first anode Anode and the first emission layer EMLa are positioned inside the first separator SEPa, and constitute the first light-emitting element together with the cathode Cathode. The first anode Anodea of the first light-emitting element may be electrically connected to the first pixel circuit unit PCa through the opening OP-cat1 positioned in the cathode Cathode and the first anode connecting part Anodea-co to receive the current from the first pixel circuit unit PCa.

In a plan view, inside the second separator SEPb, the second anode Anodeb and the second emission layer EMLb are positioned, and constitute the second light-emitting element together with the cathode Cathode. The second anode Anodeb of the second light-emitting element may be electrically connected to the second pixel circuit unit PCb through the opening OP-cat2 positioned in the cathode Cathode and the second anode connecting part Anodeb-co to receive the current from the second pixel circuit unit PCb.

In a plan view, inside the third separator SEPc, the third anode Anodec and the third emission layer EMLc are positioned, and constitute the first light-emitting element together with the cathode Cathode. The third anode Anodec of the first light-emitting element may be electrically connected to the third pixel circuit unit PCc through the opening OP-cat2 positioned in the cathode Cathode and the third anode connecting part Anodec-co to receive the current from the third pixel circuit unit PCc.

The light emitting display device having the planar structure of FIG. 16 as above-described is described in more detail through the cross-sectional structure of FIG. 17.

FIG. 17 is a cross-sectional view of a light emitting display device according to the embodiments of FIG. 16.

FIG. 17 shows one light-emitting element among the first light-emitting element, the second light-emitting element, and the third light-emitting element, and a path through which the current is transmitted to the anode Anodea from one transistor of the pixel circuit units PCa, PCb, and PCc is shown along with the separator SEP and the opening OPcon, which are positioned in the pixel definition layer 380.

Some repetitive description of the same parts as FIG. 2 among the structure to the interlayer insulating layer 161 may be omitted in FIG. 17. In the embodiments illustrated with respect to FIG. 17, the cathode Cathode positioned on the interlayer insulating layer 161 is connected to the driving low voltage line 174 through the opening OP1 to receive the driving low voltage ELVSS as a difference from the structure of FIG. 2.

In FIG. 17, the structure above the interlayer insulating layer 161 is described in detail as follows.

A cathode layer including a cathode Cathode and an anode connecting part Anode-co is formed on an interlayer insulating layer 161. The anode connecting part Anode-co is positioned within the opening OP-cat of the cathode cathode and is electrically separated from the cathode Cathode. A part of the cathode Cathode may be a separator overlapping cathode part Cathode-sep overlapping the separator SEP, and a part of another cathode Cathode may overlap the emission layer EML of the light-emitting element.

The cathode layer may be composed of a single layer including a transparent conductive oxide film or a metal material or a multi-layer including these. The transparent conductive oxide layer may include indium tin oxide (ITO), poly-ITO, indium zinc oxide (IZO), indium gallium zinc oxide (IGZO), and indium tin zinc oxide (ITZO). The metal material may include silver (Ag), molybdenum (Mo), copper (Cu), gold (Au), and aluminum (Al).

An auxiliary insulating layer SIL is positioned on the cathode layer. The auxiliary insulating layer SIL may be positioned only on the cathode layer and may not be positioned on the interlayer insulating layer 161. The auxiliary insulating layer SIL may include an under-cut portion UC where the auxiliary insulating layer SIL is removed and not formed, and may be positioned above the separator overlapping cathode part Cathode-sep and at a part where the separator SEP is formed. Due to the under-cut portion UC where the auxiliary insulating layer SIL is not formed, a layer (e.g., the anode) positioned on the separator SEP may be separated based on the separator SEP. Also, among the cathode layer, an area where the auxiliary insulating layer SIL is positioned may vary according to some embodiments. Here, the auxiliary insulating layer SIL may be formed of an inorganic insulating layer including a silicon oxide (SiOx), a silicon nitride (SiNx), a silicon oxynitride (SiOxNy), etc., or an organic insulator including at least one material selected from a group consisting of polyimide, polyamide, acryl resin, benzocyclobutene, and phenol resin.

On the cathode layer and the auxiliary insulating layer SIL, a pixel definition layer 380 having openings OP and OPcon and a separator SEP is formed.

The opening OP of the pixel definition layer 380 is a part corresponding to the light-emitting element and/or the emission layer EML, and exposes a part of the cathode Cathode.

The opening OPcon of the pixel definition layer 380 is an opening exposing a portion of the anode connecting part Anode-co, and may be an opening for connecting the anode connecting part Anode-co and the anode Anodea.

The separator SEP exposes a part of the cathode Cathode, and two anodes Anodea and Anodeb are separated based on the separator SEP.

The openings OP and OPcon and the separator SEP positioned on the pixel definition layer 380 may not expose the auxiliary insulating layer SIL, and the auxiliary insulating layer SIL may not be formed by removing the auxiliary insulating layer SIL near the separator SEP, thereby the cut portion UC may be further positioned.

The emission layer EML is positioned within the opening OP of the pixel definition layer 380, and the second functional layer FL2 may be positioned between the cathode Cathode and the emission layer EML. In addition, a first functional layer FL1 may be positioned on top of the emission layer EML. Here, the first functional layer FL1 may include a hole injection layer and/or a hole transport layer, and the second functional layer FL2 may include an electron transport layer and/or an electron injection layer. Here, the functional layer FL and the emission layer EML may be combined to be referred to as an intermediate layer. According to some embodiments, the first functional layer FL1 and the second functional layer FL2 may also be formed on the pixel definition layer 380 and the openings OP and OPcon, and in this case, both sides may be separated from each other based on the separator SEP. At this time, the first functional layer FL1 and the second functional layer FL2 are not positioned within the opening OPcon of the pixel definition layer 380, so that the anode connecting part Anode-co and the anode Anodea may be electrically connected, but problems do not occur.

On the first functional layer FL1, on the pixel definition layer 380 and the openings OP and OPcon, an anode layer including anodes Anodea and Anodeb, and a separator overlapping anode part Anode-f, are formed. Referring to FIG. 17, the separator overlapping anode part Anode-f may be positioned on the separator overlapping cathode part Cathode-sep exposed by the separator SEP. The separator overlapping anode part Anode-f may be formed in a part of the separator SEP, but it is separated from the anodes Anodea and Anodeb on both sides based on the separator SEP. Here, the separator overlapping anode part Anode-f is floating and a voltage may not be applied.

In the embodiments illustrated with respect to FIG. 17, to disconnect the anodes Anodea and Anodeb from the separator overlapping anode part Anode-f based on the separator SEP may be due to the under-cut portion UC where the auxiliary insulating layer SIL positioned under the pixel definition layer 380 is removed while being over-etched. That is, because the openings OP and OPcon and the separator SEP positioned in the pixel definition layer 380 have the tapered sides, a layer positioned thereon is continuously stacked, but a layer may be broken and separated due to the under-cut portion UC positioned below the separator SEP.

On the other hand, according to some embodiments, a functional layer FL may be positioned between the separator overlapping cathode part Cathode-sep and the separator overlapping anode part Anode-f. At this time, the functional layer FL may also have a separator overlapping functional layer like the separator overlapping anode part Anode-f, and may have a structure separated from the functional layers on both sides.

Referring to FIG. 17, the part that serves as the second electrode of the semiconductor layer ACT of the transistor and the anode connecting part Anode-co are electrically connected through the opening OP1 positioned in the interlayer insulating layer 161, and the anode connecting part Anode-co transmits the current to the anode Anode through the opening OPcon.

The current transmitted to the anode Anodea is transmitted to the cathode Cathode through the first functional layer FL1, the emission layer EML, and the second functional layer FL2, and the emission layer EML emits light due to the current flowing to the emission layer EML, thereby the light-emitting element represents luminance.

FIG. 17 is the cross-sectional structure according to some embodiments, and numerous variations structures may be possible.

The embodiments in which the current output from the driving transistor T1 of the pixel circuit units PCa, PCb, and PCc is transmitted to the anode of the light-emitting element has been described.

However, according to some embodiments, the current output from the driving transistor T1 of the pixel circuit units PCa, PCb, and PCc may be transferred to the cathode of the light-emitting element, and the first driving voltage ELVDD may be applied to the anode. Such embodiments are also referred to as an inverted pixel structure, and aspects of some embodiments having the inverted pixel structure are described in more detail below.

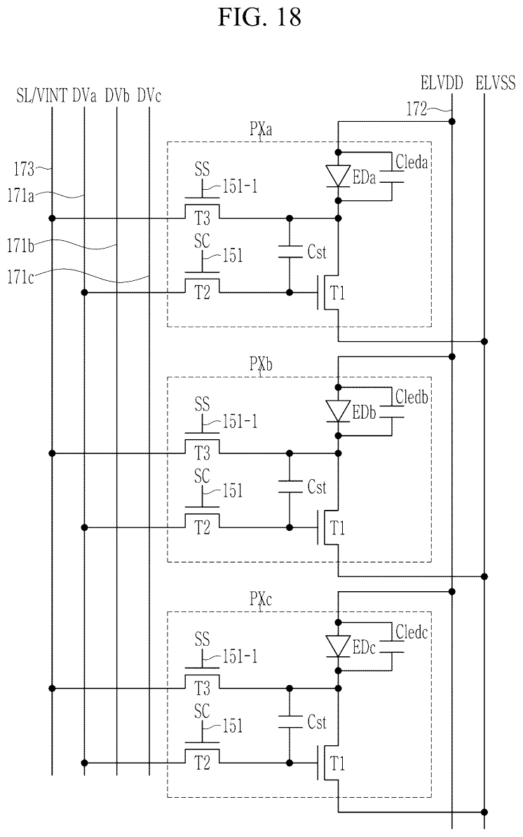

First, the circuit structure of the inverted pixel is described through FIG. 18.

In the inverted pixel, the light-emitting elements EDa, EDb, and EDc represent a luminance depending on the magnitude of the current flowing to a current path connected from the driving voltage line 172 to which the first voltage ELVDD is applied to the driving low voltage line 174 to which the second voltage ELVSS is applied through the first transistor T1, and the larger the current, the higher the displayed luminance may be. In the inverted pixel structure illustrated with respect to FIG. 18, because the first electrode of the first transistor T1 is connected to the light-emitting element LED and is separated from the second electrode (a source electrode) of the first transistor T1, each part of the pixel driving circuit unit may have a merit of having no change in the voltage of the second electrode (the source electrode) of the first transistor T1 when the voltage is changed.

FIG. 18 is a circuit diagram of a pixel of a light emitting display device according to some embodiments.

The embodiments illustrated with respect to FIG. 18 are embodiments in which one of pixels PXa, PXb, and PXc includes one light-emitting element EDa, EDb, and EDc, like FIG. 15. However, unlike FIG. 15, the light-emitting elements EDa, EDb, and EDc are positioned between the driving voltage line 172 for transmitting the driving voltage ELVDD and the first electrode of the driving transistor T1, the anodes of the light-emitting elements EDa, EDb, and EDc are connected to the driving voltage line 172, and the cathode of the light-emitting elements EDa, EDb, and EDc is connected to the first electrode of the driving transistor T1.

Also, the initialization transistor T3 is connected to the cathode of the light-emitting elements EDa, EDb, and EDc.

For example, the circuit structure of the inverted pixel according to the embodiments of FIG. 18 may be as follows.

The gate electrode of driving transistor T1 is connected to one terminal of the storage capacitor Cst, and is also connected to the second electrode (an output side electrode) of the input transistor T2. Also, the first electrode of the driving transistor T1 is connected to the cathode of the light-emitting elements EDa, EDb, and EDc, the other terminal of the storage capacitor Cst, and the first electrode of the initialization transistor T3, and the second electrode of the driving transistor T1 is connected to the driving low voltage line 174 for transmitting the driving low voltage ELVSS. The driving transistor T1 receives the data voltages DVa, DVb, and DVc as the gate electrode according to the switching operation of the input transistor T2, and the driving current may be supplied to the light-emitting elements EDa, EDb, and EDc according to the voltage of the gate electrode. At this time, the storage capacitor Cst stores and maintains the voltage of the gate electrode of the driving transistor T1.

The gate electrode of the input transistor T2 is connected to the first scan signal line 151 transmitting the first scan signal SC. The first electrode of the input transistor T2 is connected to the data lines 171a, 171b, and 171c that transmit the data voltages DVa, DVb, and DVc, and the second electrode of the input transistor T2 is connected to one terminal of the storage capacitor Cst and the first electrode of the driving transistor T1. A plurality of data lines 171a, 171b, and 171c transmit the different data voltages DVa, DVb, and DVc, respectively, and the input transistor T2 of each pixel PXa, PXb, and PXc is connected to the different data lines 171a, 171b, and 171c. The gate electrode of the input transistor T2 of each pixel PXa, PXb, and PXc is connected to the same first scan signal line 151, thereby receiving the first scan signal SC at the same timing. Even if the input transistor T2 of each pixel PXa, PXb, and PXc is turned on simultaneously by the first scan signal SC of the same timing, the different data voltages DVa, DVb, and DVc are transmitted to one terminal of the storage capacitor Cst and the gate electrode of the driving transistor T1 of each pixel PXa, PXb, and PXc through the different data lines 171a, 171b, and 171c.

The gate electrode of the initialization transistor T3 is connected to the second scan signal line 151-1 that transmits the second scan signal SS. The first electrode in of the itialization transistor T3 is connected to the other terminal of the storage capacitor Cst, the first electrode of the driving transistor T1, the cathode of the light-emitting elements EDa, EDb, and EDc and one terminal of the light-emitting part capacitors Cleda, Cledb, and Cledc, and the second electrode of the initialization transistor T3 is connected to the initialization voltage line 173 transmitting the initialization voltage VINT. As the initialization transistor T3 is turned on according to the second scan signal SS, the initialization voltage VINT is transmitted to the cathode of the light-emitting elements EDa, EDb, and EDc, one terminal of the light-emitting part capacitors Cleda, Cledb, and Cledc, and the other terminal of the storage capacitor Cst to initialize the voltage of the cathode of the light-emitting elements EDa, EDb, and EDc.

The initialization voltage line 173 may serve as detection wiring SL by performing an operation of detecting the voltage of the cathodes of the light-emitting elements EDa, EDb, and EDc before applying the initialization voltage VINT. Through the detection operation, it is possible to check whether the voltage of the cathode is maintained at the target voltage. The detection operation and the initialization operation that transmits the initialization voltage VINT may be performed to be distinguished in time, and the initialization operation may be performed after the detection operation is performed.

In the embodiments illustrated with respect to FIG. 18, the turn-on periods of the initialization transistor T3 and the input transistor T2 may be distinguished, so that the writing operation performed by the input transistor T2 and the initialization operation (and/or the detection operation) performed by the initialization transistor T3 may be performed at different timings.

One terminal of the storage capacitor Cst is connected to the gate electrode of the driving transistor T1 and the second electrode of the input transistor T2, and the other terminal thereof is connected to the first electrode of the initialization transistor T3, the first electrode of the driving transistor T1, the cathode of the light-emitting elements EDa, EDb, and EDc and one terminal of the light-emitting part capacitors Cleda, Cledb, and Cledc.

The anodes of the light-emitting elements EDa, EDb, and EDc are connected to the driving voltage line 172 that applies the driving voltage ELVDD, and the cathodes of the light-emitting elements EDa, EDb, and EDc are connected to the first electrode of the driving transistor T1. The light-emitting elements EDA, EDb, and EDc emit light according to the output current of the driving transistor T1, thereby displaying grays.

In addition, the light-emitting part capacitors Cleda, Cledb, and Cledc are formed on both terminals of the light-emitting elements EDa, EDb, and EDc so that the voltage of both terminals of the light-emitting elements EDa, EDb, and EDc may be kept constant so that the light-emitting elements EDA, EDb, and EDc may display a constant luminance.

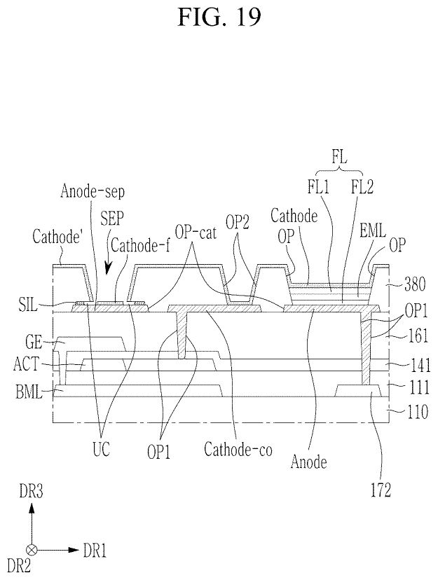

In the following, various embodiments of the pixel of the inverted structure as shown in FIG. 18 are described with reference to FIG. 19 to FIG. 21.

FIG. 19 to FIG. 21 are cross-sectional views of a light emitting display device according to some embodiments.

First, the embodiments illustrated with respect to FIG. 19 are described as follows.

In the embodiments illustrated with respect to FIG. 19, cathodes Cathode and Cathode′ are separated by using separators SEPa, SEPb, and SEPc, and the anode Anode is positioned under a pixel definition layer 380. The cathode Cathode is connected to the cathode connecting part Cathode-co through the opening OP2 positioned in the pixel definition layer 380, and receives the current from the driving transistor of the pixel circuit unit.

In FIG. 19, some repetitive description of the same portions as in FIG. 17 among the structure to the interlayer insulating layer 161 may be omitted. In the embodiments illustrated with respect to FIG. 19, the anode Anode positioned on the interlayer insulating layer 161 is connected the driving voltage line 172 through an opening OP1 to receive the driving voltage ELVDD.

In FIG. 19, the structure of the interlayer insulating layer 161 is described in detail as follows.

On the interlayer insulating layer 161, the anode layer including the anode Anode, the cathode connecting part Cathode-co, and the separator overlapping anode part Anode-sep is formed. Here, the cathode connecting part Cathode-co is electrically separated from the anode Anode. A part of the anode Anode may be a separator overlapping anode part Anode-sep overlapping the separator SEP, and a part of another anode Anode may overlap the emission layer EML of the light-emitting element.

The anode layer may be composed of a single layer including a transparent conductive oxide film, a metal material, or a multi-layer including the same. The transparent conductive oxide layer may include indium tin oxide (ITO), poly-ITO, indium zinc oxide (IZO), indium gallium zinc oxide (IGZO), and indium tin zinc oxide (ITZO). The metal material may include silver (Ag), molybdenum (Mo), copper (Cu), gold (Au), and aluminum (Al).

On the anode layer, an auxiliary insulating layer SIL is positioned. The auxiliary insulating layer SIL may be positioned only on the anode layer and may not be positioned on the interlayer insulating layer 161. In the auxiliary insulating layer SIL, above the separator overlapping anode part Anode-sep, in the portion where the separator SEP is formed, the under-cut portion UC, which the auxiliary insulating layer SIL, is removed and is not formed, may be positioned. Due to the under-cut portion UC where the auxiliary insulating layer SIL is not formed, a layer (e.g. a cathode) positioned on the separator SEP may be separated based on the separator SEP. Also, among the anode layer, the area where the auxiliary insulating layer SIL is positioned may vary according to some embodiments. Here, the auxiliary insulating layer SIL may be formed of an inorganic insulating layer including a silicon oxide (SiOx), a silicon nitride (SiNx), a silicon oxynitride (SiOxNy), etc., or an organic insulator including at least one material selected from a group consisting of polyimide, polyamide, acryl resin, benzocyclobutene, and phenol resin.

On the anode layer and the auxiliary insulating layer SIL, a pixel definition layer 380 in which openings OP and OP2 and a separator SEP are formed is formed.

The opening OP of the pixel definition layer 380 is a part corresponding to the light-emitting element and/or emission layer EML and exposes a part of the anode Anode.

The opening OP2 of the pixel definition layer 380 is an opening exposing a part of the cathode connecting part Cathode-co and may be an opening for connecting the cathode connecting part Cathode-co and the cathode cathode.

The separator SEP exposes a part of the separator overlapping anode part anode-sep, and two cathodes Cathode and Cathode′ are separated based on the separator SEP.

The openings OP and OP2 and the separator SEP positioned in the pixel definition layer 380 may not expose the auxiliary insulating layer SIL, and the auxiliary insulating layer SIL may further include an under-cut portion UC where the auxiliary insulating layer SIL is removed and is not formed near the separator SEP.

The emission layer EML is positioned within the opening OP of the pixel definition layer 380, and the first functional layer FL1 may be positioned between the anode and the emission layer EML. In addition, a second functional layer FL2 may be positioned on the emission layer EML. Here, the first functional layer FL1 may include a hole injection layer and/or hole transport layer, and the second functional layer FL2 may include an electron transport layer and/or electron injection layer. Here, the functional layer FL and the emission layer EML may be combined to be referred to as an intermediate layer. According to some embodiments, the first functional layer FL1 and the second functional layer FL2 may also be formed on the pixel definition layer 380 and the opening OP, and in this case, both sides may be separated from each other based on the separator SEP. At this time, the first functional layer FL1 and the second functional layer FL2 are not positioned within the opening OP2 of the pixel definition layer 380, so that a problem may not occur when the cathode connecting part Cathode-co and the cathode athode are electrically connected.

On the second functional layer FL2, on the pixel definition layer 380 and the openings OP and OP2, an anode layer including cathodes Cathode and Cathode′ and a separator overlapping the cathode part Cathode-f is formed. Referring to FIG. 19, the separator overlapping the cathode part Cathode-f may be positioned on the separator overlapping the anode part Anode-sep exposed by the separator SEP. The separator overlapping cathode part Cathode-f may be formed on a part of the separator SEP, but it is separated from both cathodes Cathode and Cathode′ based on the separator SEP. Here, the separator overlapping cathode part Cathode-f may be floating and no voltage may be applied or it may be electrically connected to one side of the cathodes Cathode and Cathode′.

In the embodiments illustrated with respect to FIG. 19, that the cathode Cathode snd Cathode′ is disconnected from the separator overlapping cathode part Cathode-f based on the separator SEP may be due to the under-cut portion UC at which the auxiliary insulating layer SIL positioned under the pixel definition layer 380 is over-etched and removed. That is, the openings OP and OP2 and the separator SEP positioned in the pixel definition layer 380 have the tapered sides so that the layer positioned thereon may be continuously stacked, but the layer may be broken and separated due to the under-cut portion UC positioned below the separator SEP.

Meanwhile, according to some embodiments, the functional layer FL may be positioned between the separator overlapping anode part Anode-sep and the separator overlapping cathode part Cathode-f. At this time, the functional layer FL may also have a separator overlapping functional layer, like the separator overlapping cathode part Cathode-f), and may have a structure that is separated from the functional layers on both sides.

Referring to FIG. 19, the part that serves as the second electrode among the semiconductor layer ACT of the transistor and the cathode connecting part Cathode-co are electrically connected through the opening OP1 positioned in the interlayer insulating layer 161, and the cathode connecting part Cathode-co transmits the current through the opening OP2 to the cathode Cathode.

The current transmitted to the cathode Cathode is transmitted to the anode Anode through the second functional layer FL2, the emission layer EML, and the first functional layer FL1, and the emission layer EML emits light due to the current flowing to the emission layer EML, thereby the light-emitting element represents the luminance.

FIG. 19 is a cross-sectional structure according to some embodiments, and numerous variation structures are possible.

In the above, the embodiments in which one inverted pixel includes one light-emitting element has been described through FIG. 19.

Hereinafter, embodiments in which one inverted pixel includes a pair of light-emitting elements is described through FIG. 20.

In FIG. 20, along with a separator SEP and an opening OP2 positioned in the pixel definition layer 380, a path of which a current is transmitted from one transistor of the pixel circuit units PCa, PCb, and PCc to the second cathode Cathode2 and the anode Anode through the first cathode Cathode1 and the first anode Anode1 is shown.

In FIG. 20, the structure of the lower part of the anode Anode and Anode1 is briefly shown, and only one transistor is shown, and the structure from the substrate 110 to the interlayer insulating layer 161 has the slight difference shown in FIG. 19 and some repetitive description thereof may be omitted.

The anode layer including the anodes Anode and Anode1 is positioned on the interlayer insulating layer 161, and the anode layer includes a separator overlapping anode part Anode-sep overlapping the separator SEP. Here, the separator overlapping anode part Anode-sep is electrically connected to one of the anodes Anode and Anode1, but may be separated from the anodes Anode and Anode1. The separator overlapping anode part Anode-sep that is electrically separated from the anodes Anode and Anode1 may be formed as a floating structure. The anode layer may be composed of a single layer including a transparent conductive oxide film or a metal material, or a multi-layer including these. The transparent conductive oxide layer may include indium tin oxide (ITO), poly-ITO, indium zinc oxide (IZO), indium gallium zinc oxide (IGZO), and indium tin zinc oxide (ITZO). The metal material may include silver (Ag), molybdenum (Mo), copper (Cu), gold (Au), and aluminum (Al).

An auxiliary insulating layer SIL is positioned on the anode layer including the anodes Anode and Anode1 and/or the separator overlapping anode part Anode-sep. The auxiliary insulating layer SIL may be positioned only on the anode layer and may not be positioned on the interlayer insulating layer 161. The auxiliary insulating layer SIL may include an under-cut portion UC, which is not formed by removing the auxiliary insulating layer SIL above the separator overlapping anode part anode-sep and at the portion where the separator SEP) is formed. Due to the under-cut portion UC where the auxiliary insulating layer SIL is not formed, a layer (for example, a cathode) positioned on the separator SEP may be separated based on the separator SEP. Also, among the anode layers, the area where the auxiliary insulating layer SIL is positioned may vary according to some embodiments. Here, the auxiliary insulating layer SIL may be formed of an inorganic insulating layer including a silicon oxide (SiOx), a silicon nitride (SiNx), a silicon oxynitride (SiOxNy), etc., or an organic insulator including at least one material selected from a group consisting of polyimide, polyamide, acryl resin, benzocyclobutene, and phenol resin.

A pixel definition layer 380 in which openings P and OP2 and a separator SEP are formed is formed on the anode layer and the auxiliary insulating layer SIL.

The opening OP of the pixel definition layer 380 is a portion corresponding to the light-emitting element and/or the emission layers EML1 and EML2, and exposes a portion of the anodes Anode1 and Anode2.

The opening OP2 of the pixel definition layer 380 is an opening for connecting the anode layer and the cathode layer, and in FIG. 20, to connect the cathode connecting part Cathode-co and the first cathode Cathode1 or connect the first anode Anode1 and the second cathode Cathode2.

The separator SEP) exposes a part of the anodes Anode and Anode1 or the separator overlapping anode part Anode-sep, and the first cathode Cathode1 and the second cathode cathode2 are separated based on the separator SEP.

The openings OP and OP2 and the separator SEP positioned in the pixel definition layer may not expose the auxiliary insulating layer SIL, and the auxiliary insulating layer SIL may be formed with an under-cut portion UC where the auxiliary insulating layer SIL is removed and not formed around the separator SEP.

Within the opening OP of the pixel definition layer 380, emission layers EML1 and EML2 may be positioned, and a first functional layer FL1 may be positioned between the first anode Anode1 and the first emission layer EML1, and between the anode Anode and the second emission layer EML2. In addition, a second functional layer FL2 may be positioned on the first emission layer EML1 and the second emission layer EML2. Here, the first functional layer FL1 may include a hole injection layer and/or hole transport layer, and the second functional layer FL2 may include an electron transport layer and/or electron injection layer. Here, the functional layer FL and the emission layer EML may be combined to be referred to as an intermediate layer. According to some embodiments, the first functional layer FL1 and the second functional layer FL2 may also be formed in the pixel definition layer 380 and the openings OP and OP2, and in this case, both sides may be separated from each other based on the separator SEP.

Above the second functional layer FL2, a cathode layer including a first cathode Cathode1, a second cathode Cathode2, and a separator overlapping cathode part Cathode-f may be positioned on the pixel definition layer 380 and the openings OP and OP2. The separator overlapping cathode part Cathode-f may be positioned on the separator overlapping anode part Anode-sep exposed by the separator SEP. The separator overlapping cathode part Cathode-f may be formed even on a part of the separator SEP, but it is separated from the first cathode Cathode1 and the second cathode Cathode2 on both sides based on the separator SEP. Here, the separator overlapping cathode part Cathode-f may be floating and no voltage may be applied.

That the first cathode Cathode1 and the second cathode Cathode 2 are disconnected from the separator overlapping cathode part Cathode-f based on the separator SEP may be due to the under-cut portion UC where the auxiliary insulating layer SIL positioned below the pixel definition layer 380 is over-etched and removed. That is, the openings OP and OP2 and the separator SEP positioned in the pixel definition layer 380 have the tapered sides so that the layer positioned thereon may be continuously stacked, but the layer may be broken and separated due to the under-cut portion UC positioned below the separator SEP.

Meanwhile, according to some embodiments, the functional layer FL may be positioned between the separator overlapping anode part Anode-sep and the separator overlapping cathode part Cathode-f. At this time, the functional layer FL may also have a separator overlapping functional layer, like the separator overlapping cathode part Cathode-f, and may have a structure that is separated from the functional layers on both sides.

The part that serves as the second electrode among the semiconductor layer ACT of the transistor and the cathode connecting part Cathode-co are electrically connected through the opening OP1 positioned in the interlayer insulating layer 161, and the cathode connecting part Cathode-co is connected to the first cathode Cathode1 through the opening OP2, thereby a current flows to the first cathode Cathode1.

The current transmitted to the first cathode Cathode1 passes through the second functional layer FL2, the first emission layer EML1, and the first functional layer FL1 and is transmitted to the first anode Anode1. At this time, the first emission layer EML1 emits light due to the current flowing through the first emission layer EML1, and the first light-emitting element exhibits luminance.

Meanwhile, the first anode Anode1 is electrically connected to the second cathode Cathode2 through the opening OP2 positioned on the pixel definition layer 380. As a result, the current is also transmitted to the second cathode Cathode2, and the current transmitted to the second cathode Cathode2 passes through the second functional layer FL2, the second emission layer EML2, and the first functional layer FL1 and is transmitted to the anode Anode. At this time, the second emission layer EML2 emits light due to the current flowing through the second emission layer EML2, and the second light-emitting element shows luminance.

Here, the anode Anode may be connected to the driving voltage line 172 to which the driving voltage ELVDD is transmitted through the opening OP1 positioned on the interlayer insulating layer 161, and the driving voltage ELVDD may be applied.

Meanwhile, according to some embodiments, a spacer may be further formed on the pixel definition layer 380, and the spacer may have a tapered side wall to have a structure to prevent the cathode from being cut.

FIG. 20 is the cross-sectional structure according to some embodiments, and numerous variation structures are possible.

In the above, the embodiments including the light-emitting element in which the anode is positioned at the lower part and the cathode is positioned at the upper part in the inverted pixel structure has been described.

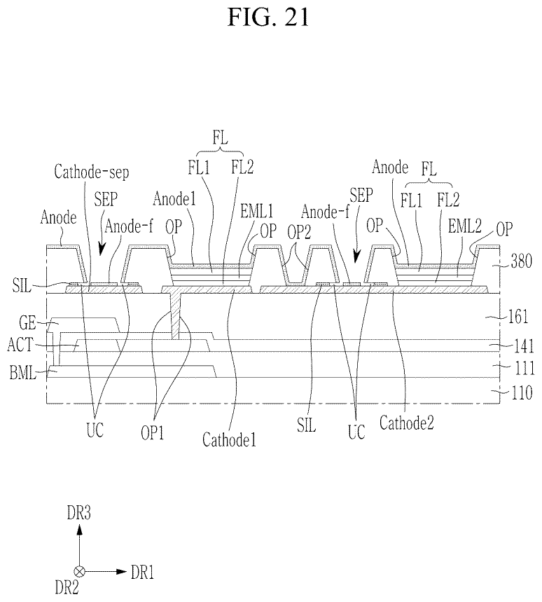

However, according to some embodiments, the cathode may be positioned at the lower part in the light-emitting element and the anode may be positioned at the upper part, and the inverted pixel structure having such a light-emitting element is described through FIG. 21.

A cathode layer including cathodes Cathode1 and Cathodes2 and a separator overlapping cathode part Cathode-sep is formed on the interlayer insulating layer 161. The separator overlapping cathode part Cathode-sep may be positioned either connected to one of the cathodes Cathode1 and Cathode2 or separated separately. The first cathode Cathode1 may overlap the opening OP of the pixel definition layer 380 and the first emission layer EML1, and a part of the second cathode Cathode2 may overlap the opening OP of the pixel definition layer 380 and the second emission layer EML2. The other part of the second cathode Cathode2 may overlap the opening OP2 of the pixel definition layer 380 to be connected to the first anode Anode1.

The cathode layer may be composed of a single layer including a transparent conductive oxide film or a metal material, or a multi-layer including these. The transparent conductive oxide layer may include indium tin oxide (ITO), poly-ITO, indium zinc oxide (IZO), indium gallium zinc oxide (IGZO), and indium tin zinc oxide (ITZO). The metal material may include silver (Ag), molybdenum (Mo), copper (Cu), gold (Au), and aluminum (Al).

An auxiliary insulating layer SIL is positioned on the cathode layer. The auxiliary insulating layer SIL may be positioned only on the cathode layer and may not be positioned on the interlayer insulating layer 161. The auxiliary insulating layer SIL may include an under-cut portion UC where the auxiliary insulating layer SIL is removed and not formed and may be positioned above the separator overlapping cathode part Cathode-sep and at a part where the separator SEP is formed. Due to the under-cut portion UC where the auxiliary insulating layer SIL is not formed, a layer (e.g., the anode) positioned on the separator SEP may be separated based on the separator SEP. Also, among the cathode layer, an area where the auxiliary insulating layer SIL is positioned may vary according to some embodiments. Here, the auxiliary insulating layer SIL may be formed of an inorganic insulating layer including a silicon oxide (SiOx), a silicon nitride (SiNx), a silicon oxynitride (SiOxNy), etc., or an organic insulator including at least one material selected from a group consisting of polyimide, polyamide, acryl resin, benzocyclobutene, and phenol resin.

On the cathode layer and auxiliary insulating layer SIL, a pixel definition layer 380 having openings OP and OP2 and a separator SEP is formed.

The opening OP of the pixel definition layer 380 is a portion corresponding to the light-emitting element and/or emission layer EML, and exposes a portion of cathodes Cathode1 and Cathode2.

The opening OP2 of the pixel definition layer 380 is an opening exposing another part of the second cathode cathode 2, and may be an opening to connect the first anode Anode1.

The separator SEP exposes a part of the separator overlapping the cathode part Cathode-sep, and two anodes Anode and Anode1 are separated based on the separator SEP.

The openings OP and OP2 and the separator SEP positioned in the pixel definition layer 380 may not expose the auxiliary insulating layer SIL, and the auxiliary insulating layer SIL further includes an under-cut portion UC where the auxiliary insulating layer SIL is removed and not formed near the separator SEP.

Within the opening OP of the pixel definition layer 380, emission layers EML1 and EML2 are respectively positioned, and the second functional layer FL2 may be positioned between the cathodes Cathode1 and Cathode2, and the emission layers EML1 and EML2, respectively. In addition, the first functional layer FL1 may be positioned on the emission layers EML1 and EML2. Here, the first functional layer FL1 may include a hole injection layer and/or hole transport layer, and the second functional layer FL2 may include an electron transport layer and/or electron injection layer. Here, the functional layer FL and the emission layer EML may be combined to be referred to as an intermediate layer. According to some embodiments, the first functional layer FL1 and the second functional layer FL2 may also be formed on the pixel definition layer 380 and the opening OP, and in this case, both sides may be separated from each other based on the separator SEP. At this time, the first functional layer FL1 and the second functional layer FL2 are not positioned within the opening OP2 of the pixel definition layer 380, so that a problem may be prevented from occurring when the second cathode Cathode2 and the first anode Anode1 are electrically connected.

On the first functional layer FL1, an anode layer including anodes Anode and Anode1, and a separator overlapping the anode part Anode-f, is formed on the pixel definition layer 380 and the openings OP and OP2. Referring to FIG. 21, a separator overlapping anode part Anode-f may be positioned on the separator overlapping cathode part Cathode-sep exposed by the separator SEP. The separator overlapping anode part Anode-f may be formed in a part of the separator SEP, but it is separated from the anodes Anode and Anode1 on both sides based on the separator SEP. Here, the separator overlapping anode part Anode-f is floating and a voltage may not be applied.

In the embodiments illustrated with respect to FIG. 21, that the anodes Anode and Anode1 are disconnected from the separator overlapping anode part Anode-f based on the separator SEP may be due to the under-cut portion UC where the auxiliary insulating layer SIL positioned under the pixel definition layer 380 is over-etched and removed. That is, the openings OP and OP2 and the separator SEP positioned in the pixel definition layer 380 have the tapered sides so that the layer positioned thereon may be continuously stacked, but the layer may be broken and separated due to the under-cut portion UC positioned below the separator SEP.

Meanwhile, according to some embodiments, the functional layer FL may be positioned between the separator overlapping cathode part Cathode-sep and the separator overlapping anode part Anode-f. At this time, the functional layer FL may also have a separator overlapping functional layer, like the separator overlapping cathode part Cathode-f, and may have a structure that is separated from the functional layers on both sides.

Referring to FIG. 21, the part serving as the second electrode of the semiconductor layer ACT of the transistor and the first cathode Cathode1 are electrically connected through the opening OP1 positioned in the interlayer insulating layer 161, and a current is transmitted to the first cathode Cathode1.

The current transmitted to the first cathode Cathode1 passes through the second functional layer FL2, the first emission layer EML1, and the first functional layer FL1 and is transmitted to the first anode Anode1, and the first emission layer EML1 emits light due to the current flowing through the first emission layer EML1, and then the first light-emitting element exhibits luminance.

Meanwhile, the first anode Anode1 is electrically connected to the second cathode Cathode2 exposed through the opening OP2 of the pixel definition layer 380, and the current transmitted to the first anode Anode1 is also transmitted to the second cathode Cathode2. The current transmitted to the second cathode Cathode2 passes through the second functional layer FL2, the second emission layer EML2, and the first functional layer FL1 and is transmitted to the anode Anode, and the current flowing through the second emission layer EML2 causes the second emission layer EML2 to emit light, and as a result, the second light-emitting element exhibits luminance.

FIG. 17 is the cross-sectional structure according to some embodiments, and numerous variation structures are possible.

In the above, according to some embodiments, the anode may be positioned below the emission layer and the cathode may be positioned above the emission layer, or the cathode may be positioned below the emission layer and the anode may be positioned above the emission layer. Instead of dividing the anode and the cathode, the electrode positioned below the emission layer may be referred to as a first light emitting electrode, and the electrode positioned above the emission layer may be referred to as a second light emitting electrode. In a case including a pair of light-emitting elements, the first light emitting electrode may include a first/first light emitting electrode and a first/second light emitting electrode, the light-emitting element opening may include a first light-emitting element opening and a second light-emitting element opening, the emission layer may include a first emission layer positioned in the first light-emitting element opening and a second emission layer positioned in the second light-emitting element opening, the second light emitting electrode includes a second/first light emitting electrode and a second/second light emitting electrode divided by a separator, the first/first light emitting electrode, the first emission layer, and the second/first light emitting electrode may configure one light-emitting element, and the first/second light emitting electrode, the second emission layer, and the second/second light emitting electrode may configure another light-emitting element.

On the other hand, the part overlapping with the separator SEP and formed of the same material on the same layer as the first light emitting electrode may be referred to as a separator overlapping first light emitting electrode part, and the part overlapping with the separator SEP and formed of the same material on the same layer as the second light emitting electrode may be called a separator overlapping second light emitting electrode part. In addition, the anode connecting part Anode-co or the cathode connecting part Cathode-co may be referred to as a second light emitting electrode connecting electrode.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SOME OF THE REFERENCE SYMBOLS

PXa, PXb, PXc: pixel PCa, PCb, PCc: pixel circuit unit
EDa, EDb, EDc, EDa1, EDa2, EDb1, EDb2, EDc1, EDc2: light-emitting element
Anode, Anode1, Anode2, Anode1a, Anode2a, Anode1b, Anode2b, Anode1c, Anode2c, Anodea, Anodeb, Anodec: anode
Anode1ae, Anode1be, Anode1ce: connection
Anode-co: anode connecting electrode Anode-m: anode layer material
Anode-f, Anode-sep: separator overlapping anode part
Anode-m1: anode layer pattern UC: under-cut
Cathode, Cathode1a, Cathode1b, Cathode1c, Cathode, Cathode′, Cathode1, Cathode2: cathode
Cathode-co, CE-cat: cathode connecting electrode
Cathode-f, Cathode-sep: separator overlapping cathode part
EML, EML1, EML2, EML1a, EML2a, EML1b, EML2b, EML1c, EML2c: emission layer
380: pixel definition layer 380-m: pixel definition layer material
380-m1: pixel definition layer pattern SIL: auxiliary insulating layer
OP, OP1, OP2, OP3, OPcon, OP-cat, OP-cat1, OP-cat2: opening
SEP, SEPa, SEPb, SEPc: separator
SIL-m1, SIL-m2, SIL-m3: auxiliary insulating layer pattern
SIL-m: auxiliary insulating layer material

| | |
|---|---|
| FL, FL1, FL2: functional layer | Mask1, Mask2: mask |
| TA: transmission region | HTA: transflective region |
| TA-c: opening transmission region | TA-s: separator transmission region |
| 151, 151-1: scan signal line | 171a, 171b, 171c: data line |
| 172: driving voltage line | 173: initialization voltage line |
| 174: driving low voltage line | 110: substrate |
| 111: buffer layer | 141: first gate insulating layer |
| 161: interlayer insulating layer | BML: lower shielding layer |
| ACT: semiconductor layer | GE: gate electrode |
| T1, T2, T3: transistor | Cst: the storage capacitor |

Cleda, Cledb, Cledc: light-emitting part capacitor

What is claimed is:

1. A light emitting display device comprising:
a first light emitting electrode;
a pixel definition layer including a light-emitting element opening exposing a part of the first light emitting electrode and including a separator;
an emission layer in the light-emitting element opening;
a second light emitting electrode divided by a separator; and
an auxiliary insulating layer between the first light emitting electrode and the pixel definition layer and in contact with the first light emitting electrode and the pixel definition layer,
wherein the separator is formed of an opening in the pixel definition layer, and an under-cut is formed under the opening in the separator.

2. The light emitting display device of claim 1, wherein
the under-cut is formed by an over-etching of the auxiliary insulating layer.

3. The light emitting display device of claim 2, wherein
the auxiliary insulating layer is not on a part where the first light emitting electrode is not formed.

4. The light emitting display device of claim 3, further comprising a separator overlapping first light emitting electrode part overlapping the separator in a plan view and formed of a same material as the first light emitting electrode.

5. The light emitting display device of claim 4, wherein
the auxiliary insulating layer and the under-cut are at an upper surface of the separator overlapping first light emitting electrode part to not be in contact with the pixel definition layer, and
a side of the separator overlapping the first light emitting electrode is in contact with the pixel definition layer.

6. The light emitting display device of claim 5, wherein the separator overlapping the first light emitting electrode is connected to the first light emitting electrode.

7. The light emitting display device of claim 5, further comprising
a separator overlapping the second light emitting electrode, and formed of a same material as the second light emitting electrode.

8. The light emitting display device of claim 7, wherein the separator overlapping the second light emitting electrode is divided from the divided second light emitting electrode.

9. The light emitting display device of claim 7, further comprising:
a second light emitting electrode connecting electrode formed of a same material as the first light emitting electrode, and
the pixel definition layer further includes a connection opening, and
the second light emitting electrode connecting electrode and the second light emitting electrode are in contact with and connected to each other through the connection opening.

10. The light emitting display device of claim 7, wherein
the pixel definition layer further includes a connection opening,
the first light emitting electrode includes a first/first light emitting electrode and a first/second light emitting electrode,
the light-emitting element opening includes a first light-emitting element opening and a second light-emitting element opening,
the emission layer includes a first emission layer in the first light-emitting element opening and a second emission layer in the second light-emitting element opening,
the second light emitting electrode includes a second/first light emitting electrode and a second/second light emitting electrode divided by the separator,
the first/first light emitting electrode, the first emission layer, and the second/first light emitting electrode configure one light-emitting element,
the first/second light emitting electrode, the second emission layer, and the second/second light emitting electrode configure another light-emitting element, and
the second/first light emitting electrode and the first/second light emitting electrode are in contact with and connected to each other through the connection opening.

11. The light emitting display device of claim 1, wherein
the auxiliary insulating layer is an inorganic insulating layer including at least one of a silicon oxide (SiOx), a silicon nitride (SiNx), or a silicon oxynitride (SiOxNy), or an organic insulator including at least one material selected from the group consisting of polyimide, polyamide, acryl resin, benzocyclobutene, and phenol resin.

12. A manufacturing method of a light emitting display device, comprising:
sequentially stacking a first conductive material and a second insulating material on a substrate;
etching the first conductive material and the second insulating material by using a first mask having a transmission region and a transflective region;
stacking a third organic insulating material on the etched first conductive material and the second insulating material; and
etching the third organic insulating material and the etched second insulating material by using a second mask including a separator transmission region to complete a separator,
the completing of the separator includes:
etching the third organic insulating material to complete a pixel definition layer and to expose the second insulating material, and
over-etching the exposed second insulating material to complete a separator having an under-cut part under the pixel definition layer.

13. The manufacturing method of the light emitting display device of claim 12, wherein the exposed second insulating material is etched by a wet-etching method in the completing of the separator having the under-cut part.

14. The manufacturing method of the light emitting display device of claim 12, wherein the separator transmission region does not overlap the transmission region and the transflective region of the first mask.

15. The manufacturing method of the light emitting display device of claim 14, wherein in the completing of the separator, a separator overlapping first light emitting electrode part overlapping the separator in a plan view and formed of the first conductive material is formed.

16. The manufacturing method of the light emitting display device of claim 15, wherein
in the completing of the separator, an auxiliary insulating layer formed on the second insulating material and an under-cut are on an upper surface of the separator overlapping first light emitting electrode part to not be in contact with the pixel definition layer, and
a side of the separator overlapping the first light emitting electrode part is formed to be in contact with the pixel definition layer.

17. The manufacturing method of the light emitting display device of claim 14, wherein the second mask further includes an opening transmission region, and
the opening transmission region overlaps the transflective region of the first mask and has a narrower width than the transflective region.

18. The manufacturing method of the light emitting display device of claim 17, wherein an opening of the pixel definition layer completed due to the opening transmission region of the second mask and the transflective region of the first mask does not expose an auxiliary insulating layer formed of the second insulating material.

19. The manufacturing method of the light emitting display device of claim 18, wherein the auxiliary insulating layer is not on a portion where a first light emitting electrode formed of the first conductive material is not positioned.

20. The manufacturing method of the light emitting display device of claim 12, wherein the second insulating material includes an inorganic insulating material including at least one of a silicon oxide (SiOx), a silicon nitride (SiNx), a silicon oxynitride (SiOxNy), or an organic insulating material including at least one material selected from the group consisting of polyimide, polyamide, acryl resin, benzocyclobutene, and phenol resin.
